(19) United States
(12) Patent Application Publication
(10) Pub. No.: US 2016/0123552 A1
(43) Pub. Date: May 5, 2016

(54) OPTICAL FILM, METHOD FOR PRODUCING OPTICAL FILM, AND SURFACE LIGHT-EMITTING BODY

(71) Applicant: MITSUBISHI RAYON CO., LTD., Chiyoda-ku, Tokyo (JP)

(72) Inventors: Daichi OKUNO, Yokohama-shi (JP); Masatoshi TODA, Tokyo (JP)

(73) Assignee: MITSUBISHI RAYON CO., LTD., Chiyoda-ku, Tokyo (JP)

(21) Appl. No.: 14/891,710

(22) PCT Filed: May 20, 2014
(86) PCT No.: PCT/JP2014/063310

§ 371 Date: Nov. 17, 2015

(30) Foreign Application Priority Data
May 23, 2013 (JP) 2013-108607

(51) Int. Cl. F21V 5/00; G02B 1/04; G02B 3/00; B29D 11/00

(52) U.S. Cl. CPC F21V 5/004; B29D 11/00365; G02B 1/041; G02B 3/0031

(57) ABSTRACT

This optical film includes a substrate and a plurality of convex microlenses arrayed on the substrate. The microlenses have an α-region and a β-region. The β-region occupies the outer portion of the convex shape of the microlenses, and is positioned in a manner so as to cover the α-region. In an adhesion test conforming to ISO 2409 for measuring the adhesiveness of the substrate and the optical film, the test result is class 0 or class 1.

### TECHNICAL FIELD

The present invention relates to an optical film, a method for producing an optical film, and a surface light-emitting body.

This application claims priority based on Japanese Patent Application No. 2013-108607 which has been filed in Japan on May 23, 2013, and the content of which is incorporated herein by reference.

### BACKGROUND ART

Among surface light-emitting bodies, an organic electroluminescent (EL) element is expected to be used in a flat panel display and also in a new generation lighting device that is used in place of a fluorescent bulb and the like.

The structure of the organic EL element is diversified, that is, from a simple structure in which an organic thin film to be a light emitting layer is merely interposed between two electrodes to a structure in which a light emitting layer is provided and an organic thin film is multi-layered. As an example of the latter multi-layered structure, those obtained by laminating a hole transporting layer, a light emitting layer, an electron transporting layer, and a negative electrode on a positive electrode formed on a glass substrate are exemplified. The layer interposed between the positive electrode and the negative electrode entirely consists of an organic thin film, and the thickness of each organic thin film is extremely thin.

The organic EL element is a laminate of thin films, and based on a difference in refractive index between materials of each thin film, the total reflection angle of the light between the thin films is determined. Under the current circumstances, about 80% of the light generated from the light emitting layer is trapped inside the organic EL element and cannot be extracted to the outside. Specifically, when the refractive index of the glass substrate is 1.5 and the refractive index of an air layer is 1.0, a critical angle θc is 41.8° and the light with the incidence angle lower than the critical angle θc is emitted from the glass substrate to the air layer. However, the light with the incidence angle higher than the critical angle θc undergoes total reflection and is trapped inside the glass substrate. For such reasons, it has been desired to extract the light trapped inside the glass substrate on the surface of the organic EL element to the outside of the glass substrate, that is, to improve light extraction efficiency.

Patent Document 1 proposes an optical film having a microlens which is covered with an outer layer formed by a vapor deposition substance with a low refractive index, in order to improve luminance of a surface light-emitting body. Patent Document 2 proposes an optical film having a lens unit including fine particles, in order to maintain uniformity of luminance of a surface light-emitting body.

### CITATION LIST

### Patent Document

Patent Document 1: JP 2011-123204 A

Patent Document 2: JP 2009-25774 A

### SUMMARY OF THE INVENTION

### Problem to be Solved by the Invention

However, regarding the optical films proposed in Patent Document 1 and Patent Document 2, improvement in optical properties, for example, improvement in luminance and uniformity of luminance are achieved but it cannot be said that improvement in other physical properties is sufficient.

Since such an optical film is covered on an outer portion in many cases, physical properties by which an external load can be endured, such as impact resistance, a low curling property, abrasion resistance, an antifouling property, flame resistance, an antistatic property, and weather resistance, are necessary. Furthermore, since such an optical film is attached to a base material or the like for use, adhesiveness with the base material or the like is necessary.

An object of the invention is to provide an optical film which is excellent in an optical property, particularly, light extraction efficiency, of a surface light-emitting body and excellent in various physical properties, particularly, adhesiveness, impact resistance, a low curling property, abrasion resistance, an antifouling property, flame resistance, an antistatic property, and weather resistance.

Furthermore, another object of the invention is to provide a method suitable for producing the optical film.

Further, still another object of the invention is to provide a surface light-emitting body which is excellent in an optical property, particularly, light extraction efficiency.

### Means for Solving Problem

(1) An optical film including a base material and a plurality of convex microlenses arranged on the base material, the microlens having an α-region and a β-region, the β-region occupying the outer portion of the convex shape of the microlens and being positioned so as to cover the α-region, in which

a resin composition constituting the α-region has a test result of class 0 or class 1 in an adhesion test in conformity with ISO 2409 for measuring adhesiveness between the base material and the resin composition constituting the α-region.

(2) The optical film described in (1), in which the resin composition constituting the α-region includes at least one unit selected from the group consisting of a monomer unit having a bisphenol skeleton and a polyfunctional urethane (meth)acrylate unit.

(3) The optical film described in (1) or (2), further including a urethane-based primer layer between the base material and the microlens.

(4) An optical film including a plurality of convex microlenses arranged therein, the microlens having an α-region and a β-region, the β-region occupying the outer portion of the convex shape of the microlens and being positioned so as to cover the α-region, in which an average value of curls at four corners when the 50 mm-square optical film is dried at 60° C. for 4 hours is 1.0 mm or less.

(5) The optical film described in (4), in which a resin composition constituting the α-region includes at least one unit selected from the group consisting of a polyoxyalkylene glycol di(meth)acrylate unit, a polyester polyol di(meth)acrylate unit, and an aromatic ester diol di(meth)acrylate unit.

(6) The optical film described in (5), in which the total content ratio of the polyoxyalkylene glycol di(meth)acrylate unit, the polyester polyol di(meth)acrylate unit, and the aromatic ester diol di(meth)acrylate unit to the total mass of the resin composition constituting the α-region is 10% by mass or more.

(7) An optical film including a plurality of convex microlenses arranged therein, the microlens having an α-region and a β-region, the β-region occupying the outer portion of the convex shape of the microlens and being positioned so as to cover the α-region, in which

a difference in light extraction efficiency of a surface light-emitting body before and after a rubbing test of reciprocating a waste cloth 1000 times with a weight of 200 g on the β-region of the optical film is −0.01% to 0.01%.

(8) The optical film described in (7), in which a resin composition constituting the β-region includes a trifunctional or higher polyfunctional (meth)acrylate unit.

(9) The optical film described in (8), in which the trifunctional or higher polyfunctional (meth)acrylate unit is at least one trifunctional or higher polyfunctional (meth)acrylate unit selected from the group consisting of pentaerythritol tri(meth)acrylate, dipentaerythritol penta(meth)acrylate, dipentaerythritol hexa(meth)acrylate, and tris(2-(meth)acryloyloxyethyl)isocyanurate.

(10) The optical film described in (8) or (9), in which a content ratio of the trifunctional or higher polyfunctional (meth)acrylate unit to the total mass of the resin composition constituting the β-region is 30% by mass or more.

(11) An optical film including a plurality of convex microlenses arranged therein, the microlens having an α-region and a β-region, the β-region occupying the outer portion of the convex shape of the microlens and being positioned so as to cover the α-region, in which a surface resistance value of the β-region in a resistivity test in conformity with IEC 60093 is 10¹³ Ω/cm² or less.

(12) The optical film described in (11), in which a resin composition constituting the β-region includes at least one material selected from the group consisting of an ionic liquid, a quaternary ammonium compound, an ionic surfactant, and a conductive polymer.

(13) The optical film described in (12), in which the resin composition constituting the β-region includes the ionic liquid.

(14) A method for producing the optical film described in any one of (1) to (13), the method including: while a roll mold having an outer peripheral surface on which a plurality of concave microlens transferring portions are arranged is rotated and a base material is allowed to travel in a rotational direction of the roll mold along the outer peripheral surface of the roll mold, coating the outer peripheral surface of the roll mold with an active energy ray curable composition B to fill a part of the concave shapes of the microlens transferring portions with the active energy ray curable composition B; supplying an active energy ray curable composition A to a space between the outer peripheral surface of the roll mold and the base material; irradiating a region between the outer peripheral surface of the roll mold and the base material with an active energy ray in a state where at least the active energy ray curable composition A is interposed between the outer peripheral surface of the roll mold and the base material to obtain cured products of the active energy ray curable composition A and the active energy ray curable composition B; and releasing the cured products from the roll mold.

(15) The method for producing the optical film described in (14), in which the application of the active energy ray curable composition B in the filling with the active energy ray curable composition B is coating for making the active energy ray curable composition B follow a surface of the concave microlens transferring portion on the outer peripheral surface of the roll mold.

(16) The method for producing the optical film described in (14) or (15), further including irradiating the active energy ray curable composition B with an active energy ray to cure the active energy ray curable composition B between the filling with the active energy ray curable composition B and the supplying of the active energy ray curable composition A.

(17) The method for producing the optical film described in any one of (14) to (16), in which a viscosity of the active energy ray curable composition B is lower than a viscosity of the active energy ray curable composition A.

(18) A surface light-emitting body including the optical film described in any one of (1) to (13).

### Effect of the Invention

The optical film of the invention is excellent in various physical properties, particularly, adhesiveness, impact resistance, a low curling property, abrasion resistance, an antifouling property, flame resistance, an antistatic property, and weather resistance.

The method for producing the optical film of the invention is suitable for producing the optical film described above.

The surface light-emitting body of the invention is excellent in an optical property, particularly, light extraction efficiency.

### BRIEF DESCRIPTION OF DRAWINGS

FIG. 1A is a schematic diagram illustrating an example of a convex microlens in an optical film of the invention;

FIG. 1B is a schematic diagram illustrating an example of the convex microlens in the optical film of the invention;

FIG. 2 is a schematic diagram illustrating an example of the optical film of the invention when viewed from the upper side of the optical film;

FIG. 3A is a schematic diagram illustrating an arrangement example of the microlens of the optical film of the invention when viewed from the upper side of the optical film;

FIG. 3B is a schematic diagram illustrating an arrangement example of the microlens of the optical film of the invention when viewed from the upper side of the optical film;

FIG. 3C is a schematic diagram illustrating an arrangement example of the microlens of the optical film of the invention when viewed from the upper side of the optical film;

FIG. 3D is a schematic diagram illustrating an arrangement example of the microlens of the optical film of the invention when viewed from the upper side of the optical film;

FIG. 3E is a schematic diagram illustrating an arrangement example of the microlens of the optical film of the invention when viewed from the upper side of the optical film;

FIG. 3F is a schematic diagram illustrating an arrangement example of the microlens of the optical film of the invention when viewed from the upper side of the optical film;

FIG. 4 is a schematic cross-sectional view illustrating an example of the optical film of the invention;

FIG. 5 is a schematic cross-sectional view illustrating an example of a surface light-emitting body of the invention; and

FIG. 6 is a schematic diagram illustrating an example of a method for producing the optical film of the invention.

### MODE(S) FOR CARRYING OUT THE INVENTION

Hereinafter, an embodiment of the invention will be described with reference to the drawings, but the invention is not limited to these drawings.

(Convex Shape of Microlens)

An optical film of the invention has a plurality of convex microlenses 10 arranged therein.

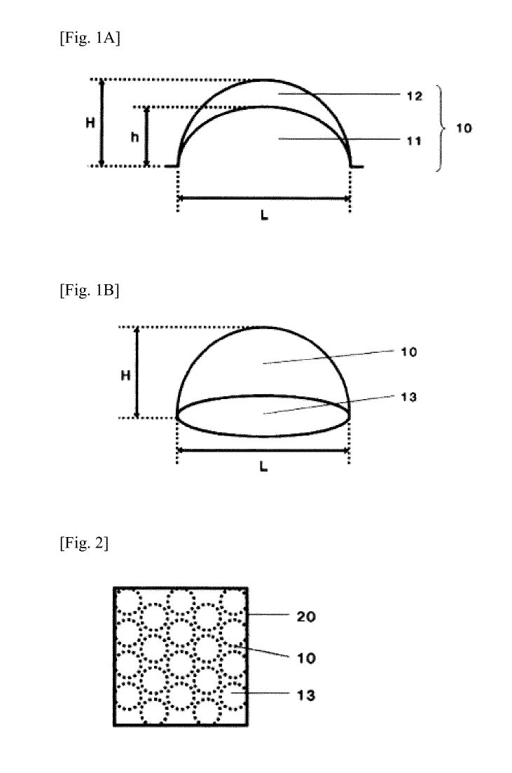

An example of the convex microlens 10 is illustrated in FIG. 1A and FIG. 1B. FIG. 1A is a schematic cross-sectional view and FIG. 1B is a schematic perspective view. The microlens 10 has an α-region 11 and a β-region 12. The β-region 12 occupies the outer portion of the convex shape of the microlens 10. The β-region 12 is positioned so as to cover the α-region 11.

It is preferable that the convex shape of the microlens 10 be formed by the outer face of the β-region 12, that is, the upper face in FIG. 1A. However, the convex shape of the microlens 10 is not limited thereto. The α-region 11 is not completely covered with the β-region 12 but a part of the α-region 11 is exposed to the outside so as to form a part of the surface of the microlens 10. In this case, the convex shape of the microlens 10 is formed by the outer face of the β-region 12 and the outer face of the α-region 11.

In the present specification, a bottom surface portion 13 of the microlens 10 is a virtual planar portion surrounded by an outer peripheral edge of a bottom portion of the microlens 10. In a case where the optical film has a base layer 21 to be described later, the bottom surface portion 13 of the microlens 10 corresponds to an interface between the microlens 10 and the base layer 21.

Furthermore, in the present specification, a maximum diameter L of the bottom surface portion 13 of the microlens 10 indicates a length of the longest part of the bottom surface portion 13 of the microlens 10, and an average maximum diameter Lₐᵥₑ of the bottom surface portion 13 of the microlens 10 is obtained by photographing the surface, which has the microlens 10, of the optical film by a scanning microscope, measuring the maximum diameter L of the bottom surface portion 13 of the microlens 10 at five positions, and averaging the values thus measured.

Furthermore, in the present specification, a height H of the microlens 10 indicates a height from the bottom surface portion 13 of the microlens 10 to the highest part of the microlens 10, and an average height Hₐᵥₑ of the microlens 10 is obtained by photographing the cross section of the optical film by a scanning microscope, measuring the height H of the microlens 10 at five positions, and averaging the values thus measured.

Further, in the present specification, a height h of the α-region 11 indicates a height from the bottom surface portion 13 of the microlens 10 to the highest part of the α-region 11, and an average height hₐᵥₑ of the α-region 11 is obtained by photographing the cross section of the optical film by a scanning microscope, measuring the height h of the α-region 11 at five positions, and averaging the values thus measured.

Examples of the convex shape of the microlens 10 include a spherical segment shape, a spherical segment trapezoidal shape, an ellipsoid spherical segment shape (a shape obtained by cutting a spheroid with one plane), an ellipsoid spherical segment trapezoidal shape (a shape obtained by cutting a spheroid with two planes that are parallel to each other), a pyramid shape, a pyramid trapezoidal shape, a conical shape, a conical trapezoidal shape, and roof-like shapes relating to these shapes (a shape in which a spherical segment shape, a spherical segment trapezoidal shape, an ellipsoid spherical segment shape, an ellipsoid spherical segment trapezoidal shape, a pyramid shape, a pyramid trapezoidal shape, a conical shape, or a conical trapezoidal shape extends along a bottom surface portion). These convex shapes of the microlens 10 may be used alone or in combination of two or more kinds thereof with respect to the plurality of microlenses 10. Among these convex shapes of the microlens 10, from the viewpoint of having excellent light extraction efficiency of the surface light-emitting body, a spherical segment shape, a spherical segment trapezoidal shape, an ellipsoid spherical segment shape, and an ellipsoid spherical segment trapezoidal shape are preferable, and a spherical segment shape and an ellipsoid spherical segment shape are more preferable.

Incidentally, the spherical shape may not be a perfect spherical shape and may be a substantially spherical shape. The substantially spherical shape indicates a shape in which the surface of the spherical shape is deviated from the surface of a virtual perfect sphere circumscribing the spherical shape or from the center of the virtual perfect sphere with respect to the normal direction, and the deviation amount thereof may be 0 to 20% relative to the radius of the virtual perfect sphere.

Furthermore, in a case where the shape is expressed as “ellipse” in the present specification, a circular shape in which a perfect circular shape extends in one direction or in multi-directions is also included.

The average maximum diameter Lₐᵥₑ of the bottom surface portion 13 of the microlens 10 is preferably 2 μm to 400 μm, more preferably 10 μm to 200 μm, and even more preferably 20 μm to 100 μm. When the average maximum diameter Lₐᵥₑ of the bottom surface portion 13 of the microlens 10 is 2 μm or more, the light extraction efficiency of the surface light-emitting body is excellent. In addition, when the average maximum diameter Lₐᵥₑ of the bottom surface portion 13 of the microlens 10 is 400 μm or less, the microlens 10 is not visually recognized and the appearance of the optical film is excellent.

The average height Hₐᵥₑ of the microlens 10 is preferably 1 μm to 200 μm, more preferably 5 μm to 100 μm, and even more preferably 10 μm to 50 μm. When the average height Hₐᵥₑ of the microlens 10 is 1 μm or more, the light extraction efficiency of the surface light-emitting body is excellent. In addition, when the average height Hₐᵥₑ of the microlens 10 is 200 μm or less, the flexibility of the optical film is excellent.

An aspect ratio of the microlens 10 is preferably 0.3 to 1.4, more preferably 0.35 to 1.3, and even more preferably 0.4 to 1.0. When the aspect ratio of the microlens 10 is 0.3 or more, the light extraction efficiency of the surface light-emitting body is excellent. In addition, when the aspect ratio of the microlens 10 is 1.4 or less, the transferring portion of the roll mold is easily formed and the production of the optical film is facilitated.

Incidentally, the aspect ratio of the microlens 10 is calculated from “the average height Hₐᵥₑ of the microlens 10/the average maximum diameter Lₐᵥₑ of the bottom surface portion of the microlens 10.”

(Bottom Surface Portion of Microlens)

Examples of the shape of the bottom surface portion 13 of the microlens 10 include a circular shape and an elliptical shape. These shapes of the bottom surface portion 13 of the convex microlens 10 may be used alone or in combination of two or more kinds thereof with respect to the plurality of microlenses 10. Among the shapes of the bottom surface portion 13 of the microlens 10, from the viewpoint of having excellent light extraction efficiency of the surface light-emitting body, a circular shape and an elliptical shape are preferable and a circular shape is more preferable.

Incidentally, the circular shape may not be a perfect circular shape and may be a substantially circular shape. The substantially circular shape indicates a shape in which the surface of the circular shape is deviated from the circumference of a virtual perfect circular shape circumscribing the circular shape with respect to the normal direction of the virtual perfect circular shape, and the deviation amount thereof may be 0 to 20% relative to the radius of the virtual perfect circular shape.

An example of the optical film viewed from the upper side thereof is illustrated in FIG. 2.

The ratio of the total area of the bottom surface portions 13 of the microlenses 10 (an area surrounded by a dotted line in FIG. 2) to an area of an optical film 20 (an area surrounded by a solid line in FIG. 2) is preferably 20 to 99%, more preferably 30 to 95%, and even more preferably 50 to 93%. When the ratio of the total area of the bottom surface portions 13 of the microlenses 10 to the area of the optical film 20 is 20% or more, the light extraction efficiency of the surface light-emitting body is excellent. In addition, when the ratio of the total area of the bottom surface portions 13 of the microlenses 10 to the area of the optical film 20 is 99% or less, the transferring portion of the roll mold is easily formed and the production of the optical film 20 is facilitated.

Incidentally, in a case where the bottom surface portions 13 of the microlenses 10 are all circular shapes of the same size, the maximum value of the ratio of the total area of the bottom surface portions of the microlenses 10 to the area of the optical film 20 is about 91%.

(Arrangement of Microlens)

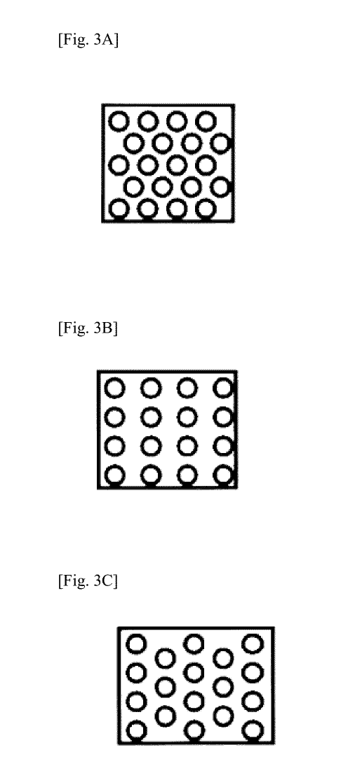

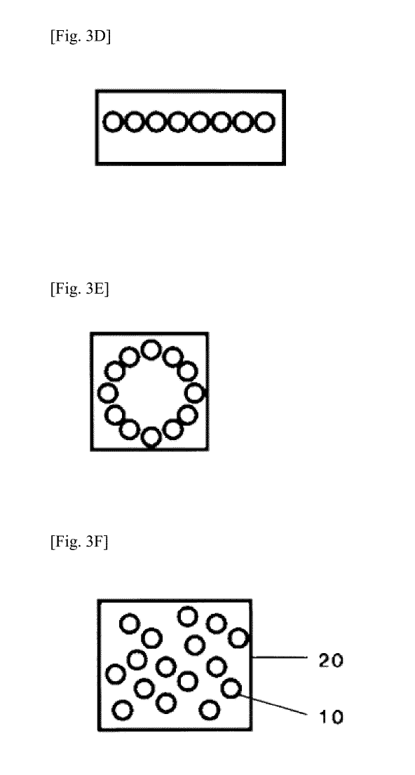

An arrangement example of the microlens 10 is illustrated in FIG. 3A to FIG. 3F.

Examples of the arrangement of the microlens 10 include hexagonal alignment (FIG. 3A), rectangular alignment (FIG. 3B), diamond alignment (FIG. 3C), linear alignment (FIG. 3D), circular alignment (FIG. 3E), and random alignment (FIG. 3F). The hexagonal alignment indicates a case where a recessed and projected structure 13 is arranged at each vertex of a hexagonal shape and the center thereof and the arrangement of the hexagonal shape is continuously aligned. The rectangular alignment indicates a case where the recessed and projected structure 13 is arranged at each vertex of a rectangular shape and the arrangement of the rectangular shape is continuously aligned. The diamond alignment indicates a case where the recessed and projected structure 13 is arranged at each vertex of a diamond shape and the arrangement of the diamond shape is continuously aligned. The linear alignment indicates a case where the recessed and projected structure 13 is arranged in a linear shape. The circular alignment indicates a case where the recessed and projected structure 13 is arranged along the circle.

Among these examples of arrangement of the microlens 10, from the viewpoint of having excellent light extraction efficiency of the surface light-emitting body, hexagonal alignment, rectangular alignment, and diamond alignment are preferable, and hexagonal alignment and rectangular alignment are more preferable.

(α-Region and β-Region)

The average height hₐᵥₑ of the α-region 11 is preferably 0.8 μm to 160 μm, more preferably 4 μm to 80 μm, and even more preferably 8 μm to 40 μm. When the average height hₐᵥₑ of the α-region 11 is 0.8 μm or more, performances (adhesiveness and impact resistance) imparted to the α-region of the optical film are excellent. In addition, when the average height hₐᵥₑ of the α-region 11 is 160 μm or less, performances (abrasion resistance, an antifouling property, flame resistance, an antistatic property, and weather resistance) imparted to the β-region of the optical film are excellent.

A ratio (hₐᵥₑ/Hₐᵥₑ) of the average height hₐᵥₑ of the α-region 11 to the average height Hₐᵥₑ of the microlens 10 is preferably 0.04 to 0.96, more preferably 0.1 to 0.92, and even more preferably 0.2 to 0.88. When the ratio of the average height hₐᵥₑ of the α-region 11 to the average height Hₐᵥₑ of the microlens 10 is 0.04 or more, the performances imparted to the α-region of the optical film are excellent. In addition, when the ratio of the average height hₐᵥₑ of the α-region 11 to the average height Hₐᵥₑ of the microlens 10 is 0.96 or less, the performances imparted to the β-region of the optical film are excellent.

A ratio of the volume of the α-region 11 to the volume of the microlens 10 is preferably 0.01 to 0.90, more preferably 0.02 to 0.80, and even more preferably 0.03 to 0.70. When the ratio of the volume of the α-region 11 to the volume of the microlens 10 is 0.01 or more, the performances imparted to the α-region of the optical film are excellent. In addition, when the ratio of the volume of the α-region 11 to the volume of the microlens 10 is 0.90 or less, the performances imparted to the β-region of the optical film are excellent.

Another region may be present between the α-region 11 and the β-region 12 in the microlens 10. The “another region” may be formed by a single layer or a plurality of layers. As the “another region,” for example, an intermediate region for improving adhesiveness between the α-region and the β-region, or the like is exemplified.

(α-Region)

The α-region is formed by a resin composition having at least one performance selected from adhesiveness, impact resistance, and a low curling property.

When the α-region has a performance of adhesiveness, the microlens 10 (the base layer 21) and the base material 22 or the microlens 10 (the base layer 21) and a glass substrate 41 can be brought into close contact with each other, the structure stability of the surface light-emitting body is excellent, the adhesive layer 23 or the like cannot be provided, and productivity and bendability of the surface light-emitting body are excellent.

In the present specification, the “adhesiveness” is evaluated by an adhesion test in conformity with ISO 2409. Specifically, the evaluation is conducted by the following method.

11 cuts reaching the base material 22 are formed on a sample in which the α-region and the β-region are formed on the base material 22 using a cutter knife to form 100 grids of lattice pattern (cross cut). The interval of the cuts is set to 2 mm in this evaluation. An adhesive cellophane tape is pressed firmly onto the lattice pattern portion and the edge of the adhesive cellophane tape is peeled off at once at an angle of 45°. Thereafter, the state of the lattice pattern is compared with the standard drawing described in ISO 2409, and the adhesiveness is evaluated with six grades of class 0 to class 5. A case where a test result is class 0 indicates the highest adhesiveness, and a case where a test result is class 5 indicates the lowest adhesiveness.

In the present embodiment, regarding the adhesiveness of the optical film 20, the result of the adhesion test in conformity with ISO 2409 is class 0 or class 1, and class 0 is preferable. Class 0 indicates “The edges of the cuts are completely smooth and there was no peeling anywhere in any lattice cell.” Class 1 indicates “There is only slight peeling of the coated film at the cross point of the cuts, and the affected cross-cut portion did not exceed 5% definitely.”

The expression “influence affected on the cross-cut portion” described in the present specification indicates the degree of missing of the lattice pattern after the adhesive cellophane tape is peeled in the test.

In order to make the α-region have the performance of adhesiveness, it is desirable that the resin composition constituting the α-region include, for example, a monomer unit having a bisphenol skeleton or a monomer unit having a skeleton with adhesiveness, such as an aromatic (meth)acrylate unit.

Examples of a monomer for constituting the monomer unit having a bisphenol skeleton include ethylene oxide-modified bisphenol A di(meth)acrylate and propylene oxide-modified bisphenol A di(meth)acrylate.

Examples of a monomer for constituting the aromatic (meth)acrylate unit include ethoxylated fluorene (meth)acrylate, phenoxyethyl (meth)acrylate, benzyl(meth)acrylate, phenylglycidylether (meth)acrylate, phenylphenol (meth)acrylate, and ethoxylated phenylphenol (meth)acrylate.

The content ratio of the monomer unit having a skeleton with adhesiveness to the total mass of the resin composition constituting the α-region is preferably 10% by mass or more, more preferably 10% by mass to 90% by mass, and even more preferably 20% by mass to 80% by mass, from the viewpoint of having excellent adhesiveness of the microlens 10 (the base layer 21).

When the α-region has the performance of impact resistance, it is possible to suppress damage of the optical film 20.

The “impact resistance” in the present specification is evaluated by the following method.

In a dropping impact deformation test in conformity with ISO 6272, a 500 g ball is dropped from the height of 50 cm, the presence and absence of generation of cracking or peeling is determined, and a case not having cracking or peeling is considered to be excellent in impact resistance.

In order to make the α-region have the performance of impact resistance, it is desirable that the resin composition constituting the α-region include, for example, a monomer unit having flexibility such as a polyfunctional urethane (meth)acrylate unit.

Examples of the monomer for constituting the polyfunctional urethane (meth)acrylate unit include a compound obtained by a reaction between a diisocyanate compound (tolylene diisocyanate, isophorone diisocyanate, xylene diisocyanate, dicyclohexylmethane diisocyanate, hexamethylene diisocyanate, or the like) and a hydroxyl group-containing (meth)acrylate (polyfunctional(meth)acrylate such as 2-hydroxyethyl(meth)acrylate, 2-hydroxypropyl(meth)acrylate, 4-hydroxybutyl(meth)acrylate, or pentaerythritol tri(meth)acrylate) and a compound obtained by reacting a hydroxyl group-containing (meth)acrylate with an isocyanate group which has been left after adding a diisocyanate compound to a hydroxyl group of alcohols (one or two or more types of alkane diol, polyether diol, polyester diol, and a spiroglycol compound).

The content ratio of the monomer unit having flexibility to the total mass of the resin composition constituting the α-region is preferably 10% by mass or more, more preferably 10% by mass to 60% by mass, and even more preferably 20% by mass to 50% by mass, from the viewpoint that it is possible to suppress damage of the optical film 20.

When the α-region has the performance of a low curling property, the curling of the optical film 20 can be suppressed and the productivity of the surface light-emitting body is excellent.

The “low curling property” in the present specification is evaluated by the following method.

The optical film 20 is cut into a size of 50 mm square, is dried at 60° C. for 4 hours, is charge-removed by a blower for removal of electrostatic charge, and is left to stand still on a flat surface such that the surface having the microlens 10 faces upward. In this state, distances (curls) from the flat surface to respective four corners of the optical film 20 are measured by a height gauge. The curling property evaluation is based on an average value (mm) of the distances of respective four corners.

In the present embodiment, the curling property of the optical film 20 is 1.0 mm or less, preferably 0.01 mm to 1.0 mm, more preferably 0.03 mm to 0.9 mm, and even more preferably 0.05 mm to 0.8 mm.

In order to make the α-region have the performance of a low curling property, it is desired that the resin composition constituting the α-region include, for example, a low-modulus monomer unit such as a polyalkylene glycol di(meth)acrylate unit, a polyester polyol dimethacrylate unit, or an aromatic ester diol di(meth)acrylate unit. These low-modulus monomer units may be used alone or in combination of two or more kinds thereof.

Examples of a monomer for constituting the polyalkylene glycol di(meth)acrylate unit include polyethylene glycol di(meth)acrylate, polypropylene glycol di(meth)acrylate, and polybutylene glycol di(meth)acrylate.

Among these low-modulus monomer units, from the viewpoint that it is possible to suppress the curling of the optical film 20, a polyalkylene glycol di(meth)acrylate unit, a polyester polyol dimethacrylate unit, and an aromatic ester diol di(meth)acrylate unit are preferable, and a polyalkylene glycol di(meth)acrylate unit is more preferable.

From the viewpoint that it is possible to suppress the curling of the optical film 20 and the productivity of the surface light-emitting body is excellent, the content ratio of the low-modulus monomer unit to the total mass of the resin composition constituting the α-region is preferably 10% by mass or more, more preferably 10% by mass to 50% by mass, and even more preferably 15% by mass to 40% by mass.

From the viewpoint that it is possible to suppress the curling of the optical film 20 and the productivity of the surface light-emitting body is excellent, the total content ratio of the polyoxyalkylene glycol di(meth)acrylate unit, the polyester polyol di(meth)acrylate unit, and the aromatic ester diol di(meth)acrylate unit is preferably 10% by mass or more, more preferably 10% by mass to 50% by mass, and even more preferably 15% by mass to 40% by mass.

Regarding the material of the base material 22 for having the performance of a low curling property, in consideration of the combination of the base material 22 with the resin composition constituting the α-region, an acrylic resin, a polycarbonate resin, a polyester resin, a styrene resin, a vinyl chloride resin, a cellulose resin, and an imide resin are preferable, an acrylic resin, a polycarbonate resin, a polyester resin, and an imide resin are more preferable, and a polyester resin is even more preferable.

Furthermore, the α-region may include first fine particles. The first fine particles included in the α-region are not particularly limited as long as they are fine particles having a light diffusion property in the wavelength range of visible light (about 400 nm to 700 nm) and known fine particles can be used. The first fine particles included in the α-region may be used alone or in combination of two or more kinds thereof

Examples of a material of the first fine particles include metals such as gold, silver, silicon, aluminum, magnesium, zirconium, titanium, zinc, germanium, indium, tin, antimony, and cerium; metal oxides such as silicon oxide, aluminum oxide, magnesium oxide, zirconium oxide, titanium oxide, zinc oxide, germanium oxide, indium oxide, tin oxide, indium tin oxide, antimony oxide, and cerium oxide; metal hydroxides such as aluminum hydroxide; metal carbonates such as magnesium carbonate; metal nitrides such as silicon nitride; and resins such as an acrylic resin, a styrene resin, a silicone resin, a urethane resin, a melamine resin, and an epoxy resin. These materials of the fine particles may be used alone or in combination of two or more kinds thereof. Among these materials of the fine particles, from the viewpoint of excellent handlability at the time of producing the optical film 20, silicon, aluminum, magnesium, silicon oxide, aluminum oxide, magnesium oxide, aluminum hydroxide, magnesium carbonate, an acrylic resin, a styrene resin, a silicone resin, a urethane resin, a melamine resin, and an epoxy resin are preferable, and particles of silicon oxide, aluminum oxide, aluminum hydroxide, magnesium carbonate, an acrylic resin, a styrene resin, a silicone resin, a urethane resin, a melamine resin, and an epoxy resin are more preferable.

From the viewpoint of having an excellent light transmitting property of the optical film 20, the refractive index of the first fine particles included in the α-region is preferably 1.30 to 2.00, more preferably 1.35 to 1.95, and even more preferably 1.40 to 1.90. The refractive index of the first fine particles is a value measured by using a sodium D line at 20° C.

The volume average particle diameter of the first fine particles included in the α-region is preferably 0.5 μm to 20 μm, more preferably 1 μm to 15 μcm, and even more preferably 1.5 μm to 10 μm. When the volume average particle diameter of the first fine particles included in the α-region is 0.5 μm or more, light in visible wavelength range can be effectively scattered. In addition, when the volume average particle diameter of the first fine particles included in the α-region is 20 μm or less, it is possible to suppress the emission angle dependence of the wavelength of light emitted from the surface light-emitting body.

Incidentally, in the present specification, the volume average particle diameter is a value measured by a coulter counter.

Examples of the shape of the first fine particles included in the α-region include a spherical shape, a column shape, a cubic shape, a rectangular shape, a pyramid shape, a cone shape, a star shape, and an amorphous shape. These shapes of the first fine particles included in the α-region may be used alone or in combination of two or more kinds thereof. Among these shapes of the first fine particles included in the α-region, from the viewpoint that light in visible wavelength range can be effectively scattered, a spherical shape, a cubic shape, a rectangular shape, a pyramid shape, and a star shape are preferable, and a spherical shape is more preferable.

The content ratio of the first fine particles included in the α-region to the total mass of the α-region is preferably 1% by mass to 50% by mass, more preferably 3% by mass to 45% by mass, and even more preferably 5% by mass to 40% by mass. When the content ratio of the first fine particles included in the α-region to the total mass of the α-region is 1% by mass or more, the light diffusion property of the optical film 20 is excellent and it is possible to suppress the emission angle dependence of the wavelength of light emitted from the surface light-emitting body. In addition, when the content ratio of the first fine particles included in the α-region to the total mass of the α-region is 50% by mass or less, the curling of the optical film 20 is suppressed and the light extraction efficiency or the luminance in the normal direction of the surface light-emitting body is excellent.

Incidentally, the content ratio of the first fine particles included in the α-region to the total mass of the α-region may be substantially the same as or different from the content ratio of the first fine particles included in an intermediate layer 25 to the total mass of the intermediate layer 25.

Furthermore, the weight average molecular weight of the resin composition constituting the α-region is preferably 500 or more, more preferably 1000 to 10000000, and even more preferably 2000 to 5000000.

(β-Region)

The β-region is formed by a resin composition having at least one performance selected from abrasion resistance, an antifouling property, flame resistance, an antistatic property, and weather resistance.

When the β-region has abrasion resistance, it is possible to suppress scratches of the optical film 20 and the optical performance of the optical film 20 or the surface light-emitting body is maintained.

The “abrasion resistance” in the present specification is evaluated by the following method. Abrasion marks are formed on the optical film 20 by reciprocating a waste cloth 1000 times in total with a weight of 200 g for a distance of 300 mm at a speed of one reciprocation/min, using a rubbing tester (model name “RT-200,” DAIEI KAGAKU SEIKI MFG. CO., LTD).

The abrasion evaluation is based on a value (%) obtained by subtracting the light extraction efficiency of the surface light-emitting body on which the optical film 20 is laminated before the rubbing test from the light extraction efficiency of the surface light-emitting body on which the optical film 20 is laminated after the rubbing test.

The abrasion resistance in the present embodiment is preferably −0.01% to 0.01%, more preferably −0.008% to 0.008%, and even more preferably −0.006% to 0.006%.

In order to make the β-region have the performance of abrasion resistance, it is desirable that the resin composition constituting the β-region include, for example, a monomer unit, which can impart abrasion resistance, such as a trifunctional or higher polyfunctional (meth)acrylate unit.

Examples of the monomer for constituting the trifunctional or higher polyfunctional (meth)acrylate unit include hexa(meth)acrylates such as dipentaerythritol hexa(meth)acrylate and caprolactone-modified dipentaerythritol hexa(meth)acrylate; penta(meth)acrylates such as dipentaerythritol penta(meth)acrylate, dipentaerythritol hydroxy penta(meth)acrylate, and caprolactone-modified dipentaerythritol hydroxy penta(meth)acrylate; tetra(meth)acrylates such as ditrimethylolpropane tetra(meth)acrylate, pentaerythritol tetra(meth)acrylate, pentaerythritol ethoxy-modified tetra(meth)acrylate, dip entaerythtol hexa(meth)acrylate, dip entaerythtol penta(meth)acrylate, and tetramethylolmethane tetra(meth)acrylate; and tri(meth)acrylates such as trimethylol propane tri(meth)acrylate, trisethoxylated trimethylol propane tri(meth)acrylate, pentaerythritol tri(meth)acrylate, ethoxylated pentaerythritol tri(meth)acrylate, tris(2-(meth)acryloyloxyethyl)isocyanurate, trimethylol propane tri(meth)acrylate modified with aliphatic hydrocarbon with 2 to 5 carbon atoms, and isocyanuric acid ethylene oxide-modified tri(meth)acrylate.

From the viewpoint that it is possible to suppress scratches of the optical film 20 and the optical performance of the optical film 20 or the surface light-emitting body is maintained, the content ratio of the monomer unit, which can impart abrasion resistance, to the total mass of the resin composition constituting the β-region is preferably 30% by mass or more, more preferably 30% by mass to 80% by mass, and even more preferably 40% by mass to 70% by mass.

When the β-region has an antifouling property, it is possible to suppress adhesion of dirt to the optical film 20 and the optical performance of the optical film 20 or the surface light-emitting body is maintained.

The “antifouling property” in the present specification is evaluated by the following method.

A static contact angle of pure water on the surface of the optical film 20 is measured by using a contact angle meter, and a case where the static contact angle is 90° or larger is considered to be excellent in the antifouling property.

In order to make the β-region have the performance of an antifouling property, it is desirable that the resin composition constituting the β-region include, for example, a compound having water/oil repellency such as a fluorine compound, a silicone compound, or a long-chain aliphatic compound.

Examples of the fluorine compound include polytetrafluoroethylene, polychlorotrifluoroethylene, polyvinylidene fluoride, polyvinyl fluoride, perfluoroalkoxy fluororesin, a tetrafluoroethylene/hexafluoropropylene copolymer, an ethylene/tetrafluoroethylene copolymer, and an ethylene/chlorotrifluoroethylene copolymer.

Examples of the silicone compound include tetramethyl orthosilicate, N-(2-aminomethyl)-3-aminopropyltrimethoxysilane trimethylsilyl azide, ethoxytrimethylsilane, [3-(2,3-epoxypropoxy)-propyl]-trimethoxysilane, octamethyl cyclotetrasiloxane, trichlorosilane, and tetrachlorosilane.

Examples of the long-chain aliphatic compound include eicosapentaenoic acid, linoleic acid, and oleic acid.

From the viewpoint that it is possible to suppress adhesion of dirt to the optical film 20 and the optical performance of the optical film 20 or the surface light-emitting body is maintained, the content ratio of the compound having water/oil repellency to the total mass of the resin composition constituting the β-region is preferably 0.1% by mass or more, more preferably 0.1% by mass to 10% by mass, and even more preferably 0.5% by mass to 5% by mass.

When the β-region has flame resistance, the spread of combustion of the optical film 20 can be suppressed or the optical film 20 can be self-extinguished.

The “flame resistance” in the present specification is evaluated by the following method.

In an inflammability test in conformity with UL94 Standard (product safety standards developed by Underwriters Laboratories Inc.), a case satisfying UL94HB or UL94V2 is considered to be excellent in flame resistance.

In order to make the β-region have the performance of flame resistance, it is desirable that the resin composition constituting the β-region include, for example, a compound having flame resistance such as a phosphoric acid ester compound or a halogen-containing compound.

Examples of the phosphoric acid ester compound include trimethyl phosphate, triethyl phosphate, tributyl phosphate, trioctyl phosphate, tributoxyethyl phosphate, triphenyl phosphate, tricresyl phosphate, cresyl diphenyl phosphate, octyldiphenyl phosphate, diisopropylphenyl phosphate, 2-naphthyl diphenyl phosphate, and cresyldi-2,6-xylenylphosphate.

Examples of the halogen-containing compound include tetrabromobisphenol A, decabromodiphenyl oxide, hexabromocyclododecane, octabromodiphenyl ether, bistribromophenoxyethane, ethylenebistetrabromophthalimide, tribromophenol, halogenated polystyrene, chlorinated polyolefin, and polyvinyl chloride.

From the viewpoint that the spread of combustion of the optical film 20 can be suppressed or the optical film 20 can be self-extinguished, the content ratio of the compound having flame resistance to the total mass of the resin composition constituting the β-region is preferably 1% by mass or more, even more preferably 1% by mass to 20% by mass, and even more preferably 3% by mass to 15% by mass.

When the β-region has an antistatic property, it is possible to suppress adhesion of dirt or dust to the optical film 20 due to static electricity or the like and the optical performance of the optical film 20 or the surface light-emitting body is maintained.

The “antistatic property” in the present specification is evaluated by a resistivity test in conformity with IEC 60093. Specifically, the evaluation is conducted by the following method.

The surface resistivity is measured by using a resistivity meter when the surface of the optical film 20 is subjected to application of a voltage of 500 V by using a ring probe and then is maintained for 60 seconds.

From the viewpoint that it is possible to suppress adhesion of dirt or dust to the optical film 20 due to static electricity or the like and the optical performance of the optical film 20 or the surface light-emitting body is maintained, the surface resistivity of the optical film 20 is preferably 10¹³ Ω/cm² or less, more preferably 10⁸ Ω/cm² to 10¹³ Ω/cm², and even more preferably 10⁹ Ω/cm² to 10¹² Ω/cm².

In order to make the β-region have the performance of an antistatic property, it is desirable that the resin composition constituting the β-region include, for example, at least one compound having conductivity of an ionic liquid, a quaternary ammonium compound, an ionic surfactant, and a conductive polymer. These compounds may be used alone or in combination of two or more kinds thereof. Among these compounds, from the viewpoint of having excellent dispersibility in a resin, an ionic liquid is preferable.

The ionic liquid indicates a salt present in a liquid form and is composed of an anion and a cation.

Examples of the anion of the ionic liquid include halogens, imides, amides, sulfates, and phosphates. These anions of the ionic liquid may be used alone or in combination of two or more kinds thereof. Among these anions of the ionic liquid, from the viewpoint of having an excellent antistatic property, imides, amides, and sulfates are preferable, and imides and sulfates are more preferable.

Examples of the halogens include tetrafluoroborate, hexafluorophosphate, chloride, tetrachloroaluminate, bromide, and iodide. These halogens may be used alone or in combination of two or more kinds thereof.

Examples of the imides include trifluoromethanesulfonimide. These imides may be used alone or in combination of two or more kinds thereof.

Examples of the amides include cyanamide and trifluoromethyl sulfonamide. These amides may be used alone or in combination of two or more kinds thereof.

Examples of the sulfates include butylsulfate, methylsulfate, ethylsulfate, hydrogen sulfate, octylsulfate, and alkylsulfate. These sulfates may be used alone or in combination of two or more kinds thereof

Examples of the phosphates include butylphosphate. These phosphates may be used alone or in combination of two or more kinds thereof

In addition to above-described examples, nitrate, thiocyanate, acetate, aminoacetate, lactate, and the like are exemplified.

Examples of the cation of the ionic liquid include ammonium salts, imidazolium salts, phosphonium salts, pyridinium salts, pyrrolidinium salts, pyrrolinium salts, and triazolium salts. These cations of the ionic liquid may be used alone or in combination of two or more kinds thereof. Among these cations of the ionic liquid, from the viewpoint of having an excellent antistatic property, ammonium salts and imidazolium salts are preferable, and ammonium salts are more preferable.

Examples of the ammonium salts include butyl trimethyl ammonium, ethyl diethyl propyl ammonium, 2-hydroxyethyl-triethyl ammonium, methyl-trioctyl ammonium, methyltrioctyl ammonium, tetrabutyl ammonium, tetraethyl ammonium, tetraheptyl ammonium, tributylmethyl ammonium, triethylmethyl ammonium, and tris(2-hydroxy)methyl ammonium. These ammonium salts may be used alone or in combination of two or more kinds thereof

Examples of the imidazolium salts include 1-allyl-3-methylimidazolium, 1-benzyl-3-methylimidazolium, 1,3-bis(cyanomethyl)imidazolium, 1,3-bis(cyanopropyl)imidazolium, 1-butyl-2,3-dimethylimidazolium, 4-(3-butyl)-1-imidazolium, 1-(3-cyanopropyl)-3-methylimidazolium, 1-ethyl-3-methylimidazolium, 1-butyl-3-methylimidazolium, 1-decyl-3-methylimidazolium, 1,3-diethoxy imidazolium, 1,3-dimethoxy-2-methylimidazolium, 1-hexyl-3-methylimidazolium, 1-methyl-3-octylimidazolium, and 1-methyl-3-propylimidazolium. These imidazolium salts may be used alone or in combination of two or more kinds thereof

Examples of the phosphonium salts include tetrabutylphosphonium, tributylmethylphosphonium, and tirhexyltetradecylphosphonium. These phosphonium salts may be used alone or in combination of two or more kinds thereof.

Examples of the pyridinium salts include 1-butyl-3-methylpyridinium, 1-butyl-4-methylpyridinium, 1-butylpyridinium, 1-ethylpyridinium, 1-(3-cyanopropyl)pyridinium, and 3-methyl-4-propylpyridinium. These pyridinium salts may be used alone or in combination of two or more kinds thereof

Examples of the pyrrolidinium salts include 1-butyl-1-methylpyrrolidinium, 2-methylpyrrolidinium, and 3-phenylpyrrolidinium. These pyrrolidinium salts may be used alone or in combination of two or more kinds thereof.

Examples of the pyrrolinium salts include 2-acetylpyrrolinium, 3-acetylpyrrolinium, and 1-(2-nitrophenyl)pyrrolinium. These pyrrolinium salts may be used alone or in combination of two or more kinds thereof.

The ionic liquid may be a commercially available ionic liquid, and examples thereof include FC series manufactured by Sumitomo 3M Limited such as “FC-4400”; and Amino Ion AS series manufactured by NIPPON NYUKAZAI CO., LTD. such as “Amino Ion AS100,” “Amino Ion AS300,” or “Amino Ion AS400.”

Examples of the quaternary ammonium compound include ammonium fluoride, ammonium chloride, ammonium bromide, ammonium iodide, ammonium hydroxide, and ammonium polyhalide.

Examples of the conductive polymer include polythiophene, polythiophene vinylene, poly(3-alkylthiophene), polyparaphenylene, polyparaphenylene vinylene, polyaniline, polypyrrole, and poly 3,4 ethylenedioxythiophene-polystyrene sulfonic acid (PEDOT-PSS).

Examples of the ionic surfactant include sodium cholate, sodium deoxycholate, sodium glycolate, sodium taurocholate, sodium taurodeoxycholate, sodium N-lauroyl sarcosinate, hexadecyltrimethyl ammonium bromide, and myristyltrimethyl ammonium bromide.

From the viewpoint that it is possible to suppress adhesion of dirt or dust to the optical film 20 due to static electricity or the like and the optical performance of the optical film 20 or the surface light-emitting body is maintained, the content ratio of the compound having conductivity to the total mass of the resin composition constituting the β-region is preferably 1% by mass or more, more preferably 1% by mass to 15% by mass, and even more preferably 3% by mass to 10% by mass.

When the β-region has weather resistance, it is possible to suppress the deterioration of the optical film 20 due to weather and the optical performance of the optical film 20 or the surface light-emitting body is maintained.

The “weather resistance” in the present specification is evaluated by the following method.

After the optical film 20 is exposed to light of an ultraviolet light wavelength range (295 nm to 450 nm) at 800 W/cm² for 350 hours, a case where the total light transmittance of the optical film 20 after exposure is 0.7 time to 1.5 times the total light transmittance of the optical film 20 before exposure is considered to be excellent in weather resistance.

In order to make the β-region have the performance of weather resistance, it is desirable that the resin composition constituting the β-region include, for example, a compound which suppresses deterioration due to weather, such as an ultraviolet absorbing agent, an ultraviolet scattering agent, a light stabilizer, or an antioxidizing agent.

Examples of the ultraviolet absorbing agent include a benzotriazole compound, a triazine compound, a benzophenone compound, and a benzoate compound.

Examples of the ultraviolet scattering agent include titanium oxide and zinc oxide.

Examples of the light stabilizer include a hindered amine compound and a phenol compound.

Examples of the antioxidizing agent include a phosphate compound, a sulfur compound, and an amine compound. The antioxidizing agent has a role of improving thermal stability or oxygen stability.

From the viewpoint that it is possible to suppress the deterioration of the optical film 20 due to weather and the optical performance of the optical film 20 or the surface light-emitting body is maintained, the content ratio of the compound, which suppresses the deterioration due to weather, to the total mass of the resin composition constituting the β-region is preferably 1% by mass or more, more preferably 1% by mass to 15% by mass, and even more preferably 3% by mass to 10% by mass.

Second fine particles may be included in the β-region. As the material, the volume average particle diameter, and the shape of the second fine particles included in the β-region, the same material, volume average particle diameter, and shape as those of the first fine particles included in the α-region described above can be used, and from the same reason, the same range is preferable.

The volume average particle diameter and the shapes of the materials of the first fine particles and the second fine particles may be the same as or different from each other.

Furthermore, the weight average molecular weight of the resin composition constituting the β-region is preferably 500 or more, more preferably 1000 to 10000000, and even more preferably 2000 to 5000000.

It is preferable that the resin composition constituting the α-region and the resin composition constituting the β-region be different from each other.

(Method for Producing Resin Composition)

As the resin composition constituting the optical film of the invention, any resin compositions can be used within a range corresponding to any one of the embodiments described above.

As a method for producing a resin composition, for example, a method of mixing a desired compound, a method of polymerizing a desired monomer, a method of performing polymerization by dispersing a desired compound in a desired monomer, and the like are exemplified.

As a method for polymerizing a monomer, for example, a method of curing a thermosetting composition containing a monomer by heating, a method of curing an active energy ray curable composition containing a monomer by irradiation of an active energy ray, and the like are exemplified. Among these methods for producing the resin, the method of curing an active energy ray curable composition containing a monomer by irradiation of an active energy ray is preferable from the viewpoint of simple steps and rapid curing speed.

Examples of the active energy ray include ultraviolet rays, electron beams, X rays, infrared rays, and visible rays. Among these active energy rays, from the viewpoint of having an excellent curing property of an active energy ray curable composition and the viewpoint that deterioration of the optical film can be suppressed, ultraviolet rays and electron beams are preferable and ultraviolet rays are more preferable.

(Configuration of Optical Film)

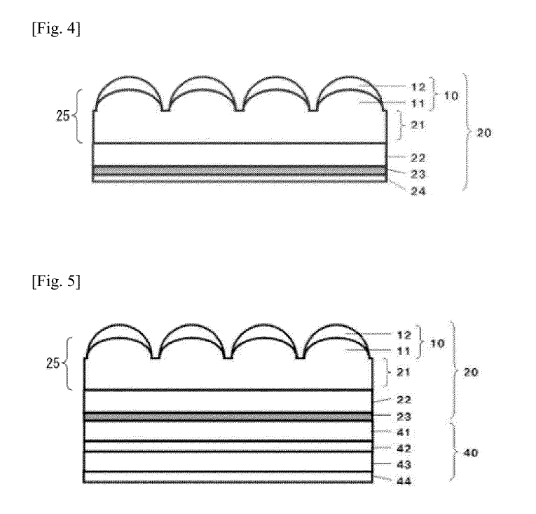

The optical film 20 according to an embodiment of the invention illustrated in FIG. 4 includes the base material 22, the convex microlens 10, the adhesive layer 23, and a protective film 24. The convex microlens 10 is disposed on the base material 22. The adhesive layer 23 and the protective film 24 are provided on the surface opposite to the surface of the base material 22 on which the convex microlens is disposed. The adhesive layer 23 is positioned between the base material 22 and the protective film 24.

From the viewpoint that the maintaining of the shape of the convex microlens 10 is excellent, it is preferable that the optical film of the invention be an optical film in which the base layer 21 is formed between the bottom surface portion of the convex microlens 10 and the base material 22 as illustrated in FIG. 4. However, the optical film of the invention is not limited thereto.

(Base Layer)

The base layer 21 mainly has a function of maintaining the convex shape of the microlens 10 by buffering stress associated with polymerization shrinkage upon curing.

As a material of the base layer 21, known resins and the like are exemplified. Among these materials of the base layer 21, from the viewpoint of simple steps and the viewpoint that the adhesiveness with the base material 22 can be enhanced by making the base layer 21 and the convex microlens 10 an integrated continuous film-like body, the material of the base layer 21 is preferably the same as the material of the α-region 11. Incidentally, the base layer 21 and the α-region 11 may be collectively called the intermediate layer 25.

The thickness of the base layer 21 is preferably 1 μm to 60 μm, more preferably 3 μm to 40 μm, and even more preferably 5 μm to 30 μm. When the thickness of the base layer 21 is 1 μm or more, the handlability of the optical film is excellent. In addition, when the thickness of the base layer 21 is 60 μm or less, the light extraction efficiency of the surface light-emitting body is excellent.

(Base Material)

In a case where the optical film, including the base material 22, is laminated on an organic EL element 40, the base material 22 is preferably formed by a material that easily transmits light of the visible light wavelength range. Specifically, regarding the visible light transmittance of the base material 18, a value measured in conformity with JIS K7361 is preferably 50% or more.

Furthermore, in a case where the active energy ray curable composition is interposed between the roll mold and the base material 22 and irradiated with an active energy ray during production of the optical film, the base material 22 is preferably formed by a material that easily transmits the active energy ray.

Examples of a material of the base material 22 include acrylic resins; polycarbonate resins; polyester resins such as polyethylene terephthalate, polybutylene terephthalate, and polyethylene naphthalate; styrene resins such as polystyrene and an ABS resin; vinyl chloride resins; cellulose resins such as diacetyl cellulose and triacetyl cellulose; imide resins such as polyimide and polyimideamide; glass; and metals. Among these materials of the base material, from the viewpoint of having excellent flexibility and an excellent light transmitting property for an active energy ray, acrylic resins, polycarbonate resins, polyester resins, styrene resins, vinyl chloride resins, cellulose resins, and imide resins are preferable, acrylic resins, polycarbonate resins, polyester resins, and imide resins are more preferable, and polyester resins are even more preferable.

The thickness of the base material 22 is preferably 10 μm to 500 μm, more preferably 20 μm to 400 μm, and even more preferably 50 μm to 300 μm. When the thickness of the base material is 10 μm or more, the handlability of the optical film is excellent. In addition, when the thickness of the base material is 500 μm or less, the light extraction efficiency of the surface light-emitting body is excellent.

(Adhesive Layer 23)

In the optical film 20 of the invention, the adhesive layer 23 for adhering to an organic EL light-emitting element 30 may be provided on the surface not having the microlens 10. When the optical film 10 includes the base material 22, the adhesive layer 23 may be provided on the surface of the base material 22 as illustrated in FIG. 4.

As the adhesive layer 23, for example, a known adhesive or the like is exemplified.

In order to enhance the handlability of the optical film 10, the protective film 24 may be provided on the surface of the adhesive layer 23. The protective film 24 may be removed from the optical film 10 or the like at the time of attaching the optical film 10 or the like to the surface of the organic EL light-emitting element 30.

As the protective film 24, for example, a known protective film or the like is exemplified.

Further, a primer layer may be formed on the surface at the side on which the microlens 10 of the base material 22 is provided. That is, the primer layer may be formed between the base material 22 and the α-region.

When the primer layer is provided on the surface of the base material 22, the adhesiveness between the base material 22 and the α-region can be made stronger. Further, it is possible to improve film formability of the α-region.

Examples of a material of the primer layer include urethane resins such as an aqueous urethane resin, an acrylic type urethane resin, an ether type urethane resin, and a polyester type urethane resin. These materials of the primer layer may be used alone or in combination of two or more kinds thereof. Among these materials of the primer layer, from the viewpoint of having excellent adhesiveness between the base material 22 and the α-region, a urethane resin is preferable, and an acrylic type urethane resin is more preferable.

(Method for Producing Optical Film)

As the method for producing the optical film of the invention, from the viewpoint of having simple steps and excellent formability of the optical film, a producing method including the following steps that are sequentially performed is preferable.

Step A: a step of, while a roll mold having an outer peripheral surface on which a plurality of concave microlens transferring portions are arranged is rotated and the base material is allowed to travel in a rotational direction of the roll mold along the outer peripheral surface of the roll mold, coating the outer peripheral surface of the roll mold with an active energy ray curable composition B to fill a part of the concave shapes of the microlens transferring portions with the active energy ray curable composition B

Step B: a step of supplying an active energy ray curable composition A to a space between the outer peripheral surface of the roll mold and the base material

Step C: a step of irradiating a region between the outer peripheral surface of the roll mold and the base material with an active energy ray in a state where the active energy ray curable composition A is interposed between the outer peripheral surface of the roll mold and the base material

Step D: a step of releasing cured products obtained in the above Step C from the roll mold

In other words, the method for producing the optical film includes: while a roll mold having an outer peripheral surface on which a plurality of concave microlens transferring portions are arranged is rotated and a base material is allowed to travel in a rotational direction of the roll mold along the outer peripheral surface of the roll mold, coating the outer peripheral surface of the roll mold with an active energy ray curable composition B to fill a part of the concave shapes of the microlens transferring portions with the active energy ray curable composition B; supplying an active energy ray curable composition A to a space between the outer peripheral surface of the roll mold and the base material; irradiating a region between the outer peripheral surface of the roll mold and the base material with an active energy ray in a state where at least the active energy ray curable composition A is interposed between the outer peripheral surface of the roll mold and the base material to obtain cured products of the active energy ray curable composition A and the active energy ray curable composition B; and releasing the cured products from the roll mold.

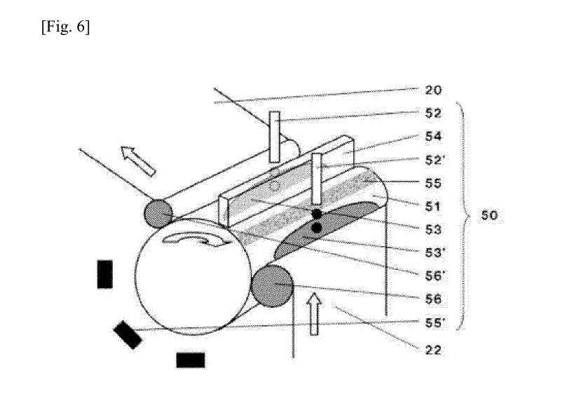

The producing method including Step A to Step D that are sequentially performed can be realized by, for example, using a producing apparatus illustrated in FIG. 6.

Hereinafter, the method for producing the optical film of the invention using the producing apparatus illustrated in FIG. 6 will be described, but the method for producing the optical film of the invention is not limited to the method using the producing apparatus illustrated in FIG. 6.

(Step A)

Step A is a step of, while a roll mold 51 having an outer peripheral surface on which a plurality of concave microlens transferring portions are arranged is rotated and the base material 22 is allowed to travel in a rotational direction of the roll mold 51 (a direction of an arrow in FIG. 6) along the outer peripheral surface of the roll mold 51, coating the outer peripheral surface of the roll mold 51 with an active energy ray curable composition B to fill a part of the concave shapes of the microlens transferring portions with the active energy ray curable composition B.

Examples of the roll mold 51 include a metal mold of aluminum, yellow copper, steel, or the like; a resin mold of a silicone resin, a urethane resin, an epoxy resin, an ABS resin, a fluororesin, a polymethylpentene resin, or the like; a plated resin mold; and a mold produced with a material in which various metal powders are mixed with a resin. Among these roll molds 51, from the viewpoint of having excellent heat resistance and mechanical strength and having suitability for continuous production, a metal mold is preferable. Specifically, the metal mold is preferred in many aspects that it is resistant to heat generated by polymerization, hardly deformed, and resistant to scratches and it allows temperature control and is suitable for fine molding or the like.

The roll mold 51 has a transferring portion of a concave shape corresponding to the convex shape in order to form the convex microlenses on the optical film 20.

Examples of a method for producing a transferring portion include cutting by a diamond bite and etching as described in WO 2008/069324 A. Among these methods for producing a transferring portion, in the case of forming a concave shape with a curved face such as a spherical segment shape, etching as described in WO 2008/069324 A is preferable from the viewpoint of having excellent productivity of the roll mold 51, and in the case of forming a concave shape without a curved face such as a pyramid shape, cutting by a diamond bite is preferable from the viewpoint of having excellent productivity of the roll mold 51.

Furthermore, as a method for producing a transferring portion, it is possible to use a method of producing a roll mold of a cylindrical form by winding a metal thin film, which is produced from a master mold having a convex shape with reversed concave shape of the transferring portion by using electroforming, on a roll core member.

The rotation speed of the roll mold 51 is preferably 0.1 m/min to 50 m/min, more preferably 0.3 m/min to 40 m/min, and even more preferably 0.5 m/min to 30 m/min, from the viewpoint of having excellent formability and productivity of the optical film.

The travel speed of the base material 22 is preferably 0.1 m/min to 50 m/min, more preferably 0.3 m/min to 40 m/min, even more preferably 0.5 m/min to 30 m/min, from the viewpoint of having excellent formability and productivity of the optical film.

The rotation speed of the roll mold 51 and the travel speed of the base material 22 are preferably similar, from the viewpoint of having excellent formability of the optical film.

Examples of a method of coating the outer peripheral surface of the roll mold 51 with the active energy ray curable composition B include a method in which the active energy ray curable composition B is added dropwise to the roll mold 51 using a nozzle 52, and then is brought into contact with a doctor blade 54 to form a bank 53, and the active energy ray curable composition B is spread and coated in a width direction of the roll mold 51; a method in which the active energy ray curable composition B is added dropwise to the roll mold 51 using the nozzle 52, and the active energy ray curable composition B is spread and coated in the width direction of the roll mold 51 under pressure from a nip roll or an air curtain; and a method in which the active energy ray curable composition B is added dropwise to the doctor blade 54, and is brought to the outer peripheral surface of the roll mold 51 along the doctor blade 54 to form the bank 53, and the active energy ray curable composition B is spread and coated in the width direction of the roll mold 51. Among these method of applying the active energy ray curable composition B, from the viewpoint that it is possible to suppress the generation of air bubbles in the microlenses and the productivity of the optical film is excellent, the method in which the active energy ray curable composition B is added dropwise to the doctor blade 54, and is brought to the outer peripheral surface of the roll mold 51 along the doctor blade 54 to form the bank 53, and the active energy ray curable composition B is spread and coated in the width direction of the roll mold 51, is preferable.

Either a single (one) or a plurality of the nozzles 52 may be provided, but from the viewpoint that the active energy ray curable composition B can be evenly coated, a single (one) nozzle 52 is preferable.

From the viewpoint that the active energy ray curable composition B can be evenly coated upon applying of the active energy ray curable composition B, it is preferable to form the bank 53 on the outer peripheral surface of the roll mold 51.

The doctor blade 54 is effective for formation of the bank 53.

Examples of a material of the doctor blade 54 include resins such as polyethylene resin, polypropylene resin, and polyester resin; and metals such as aluminum and stainless steel. Among these materials of the doctor blade 54, from the viewpoint of having excellent flexibility and the viewpoint that it is possible to suppress scratches of the roll mold 51, resins are preferable, and particularly, polyester resin is preferable.

Instead of the doctor blade 54, a roll coater, a bar coater, and the like may be used.

In order to extract light emitted from the organic EL element more through the β-region to the outside, it is preferable that the surface of the α-region be covered with the β-region as much as possible. To that end, the application of the active energy ray curable composition B in Step A is preferably coating for making the active energy ray curable composition B follow a surface of the concave microlens transferring portion on the outer peripheral surface of the roll mold 51. Making the active energy ray curable composition B follow a surface of the concave microlens transferring portion upon coating means that the active energy ray curable composition B flows while being pressed against the surface of the microlens transferring portion, to thereby form a convex surface following at least a part of the surface of the microlens transferring portion.

As a method of coating that makes the active energy ray curable composition B follow the surface of the microlens transferring portion, for example, a method of forming the bank 53 of the active energy ray curable composition B while pressing the doctor blade 54 having a tapered sharp edge, a roll coater, or a bar coater against the surface of the rotating roll mold 51, and applying a shearing force to the active energy ray curable composition B by a peripheral edge portion of the concave microlens transferring portion as well as the doctor blade 54, the roll coater, or the bar coater, to thereby generate surface tension acting on the surface of the active energy ray curable composition B following the concave shape, is exemplified.

According to this, it is possible to suppress the generation of air bubbles in the optical film, the α-region can be covered with the β-region as much as possible, and the role of the β-region in the optical film can be sufficiently exerted.

The base material 22 is preferably pressed by a nip roll 56 and a hold-down roll 56′ toward the roll mold 51, from the viewpoint that the thickness of the base layer can be controlled.

Examples of materials of the nip roll 56 and the hold-down roll 56′ include a metal such as aluminum, stainless steel, or brass; and the above-described metal with a rubber layer on a surface thereof. Among these materials of the nip roll 56 and the hold-down roll 56′, a metal with a rubber layer on a surface thereof is preferable.

Examples of a rubber material of the rubber layer include ethylene-propylene rubber, butadiene rubber, urethane rubber, nitrile rubber, and silicone rubber. Among these rubber materials of the rubber layer, from the viewpoint of having excellent active energy ray resistance, ethylene-propylene rubber and silicone rubber are preferable.

The rubber layer on the surfaces of the nip roll 56 and the hold-down roll 56′ is preferably 20 to 90 degrees, more preferably 40 to 85 degrees, and even more preferably 50 to 80 degrees in rubber hardness defined by JIS-K-6253. When the rubber hardness of the rubber layer is 20 degrees or more, a suppression action of generation of air bubbles in the optical film is excellent. In addition, when the rubber hardness of the rubber layer is 90 degrees or less, a strain applied to the base material 22 is decreased and a suppression action of damage of the base material 22 is excellent.

In order to make the active energy ray curable composition B follow a concave surface of the outer peripheral surface of the roll mold 51, in addition to the above-described method, it is preferable to control the viscosity of the active energy ray curable composition B or the temperature during applying the active energy ray curable composition B. The reason for this is that, by controlling the viscosity or the temperature, a contact angle (wettability) upon contact between the concave shape of the outer peripheral surface of the roll mold 51 and the active energy ray curable composition B is determined and possibility of coating that follows the surface of the concave shape is determined. For example, there is a tendency that if the viscosity of the active energy ray curable composition B is too low, the active energy ray curable composition B stays only in a deep part of the concave shape and it is difficult to make follow the surface of the concave shape sufficiently, and if the viscosity of the active energy ray curable composition B is too high, the active energy ray curable composition B does not flow to the deep part of the concave shape and it is difficult to make follow the surface of the concave shape sufficiently.

The viscosity of the active energy ray curable composition B will be described later.

The temperature during applying the active energy ray curable composition B is preferably 10 to 90° C. and more preferably 20 to 80° C., from the viewpoint that the active energy ray curable composition B can be coated to follow the surface of the concave shape of the outer peripheral surface of the roll mold 51.

The temperature during applying the active energy ray curable composition B may be controlled by providing heat source equipment such as a sheath heater and a hot water jacket as necessary, inside or outside the roll mold 51.

(Step X)

In a case where it is desired to define an interface clearly between the α-region and the β-region in the microlens of the optical film 20, a step of irradiating the active energy ray curable composition B with an active energy ray to cure the active energy ray curable composition B (Step X) is preferably included before Step B.

Incidentally, in a case where there is no Step X, the vicinity of the interface between the α-region and the β-region in the microlens is gradated so that the vicinity of the interface between the α-region and the β-region becomes a region including components of both the α-region and the β-region.

As a method of irradiating with an active energy ray, for example, a method using an active energy ray irradiation device 55 is exemplified.

Irradiation of the active energy ray by the active energy ray irradiation device 55 is preferably performed uniformly in a width direction of the roll mold. Irradiation of the active energy ray that is uniform in the width direction of the roll mold can be realized, for example, by connecting a light incident end of a line light composed of optical fibers to an ultraviolet lamp and arranging a linear light exit end of the line light in the vicinity of the roll mold such that a line direction is the width direction of the roll mold.

The accumulated light quantity of the active energy ray by the active energy ray irradiation device 55 is preferably 0.01 J/cm² to 5 J/cm² and more preferably 0.1 J/cm² to 3 J/cm², from the viewpoint of having an excellent curing property of the active energy ray curable composition B and the viewpoint that the accumulated light quantity does not interfere with the coating of the active energy ray curable composition A.

A light shielding plate may be provided around the active energy ray irradiation device 55 as necessary, for preventing the active energy ray from the active energy ray irradiation device 55 from diffusing to cure the active energy ray curable composition A before being coated.

(Step B)

Step B is a step of supplying the active energy ray curable composition A to a space between the outer peripheral surface of the roll mold 51 and the base material 22.

Examples of a method of supplying the active energy ray curable composition A to a space between the outer peripheral surface of the roll mold 51 and the base material 22 include a method in which the active energy ray curable composition A is added dropwise to the roll mold 51 coated with the active energy ray curable composition B using a nozzle 52′, and then is brought into contact with the nip roll 56 through the base material 22 to form a bank 53′, and the active energy ray curable composition A is spread and coated in the width direction of the roll mold 51; and a method in which the surface of the base material 22 is coated with the active energy ray curable composition A in advance, and then the roll mold 51 coated with the active energy ray curable composition B and the base material 22 coated with the active energy ray curable composition A are joined so as to perform coating. Among these methods of applying the active energy ray curable composition A, from the viewpoint that it is possible to suppress the generation of air bubble in the microlenses and it is easy to control the thickness of the base layer, the method in which the active energy ray curable composition A is added dropwise to the roll mold 51 coated with the active energy ray curable composition B using the nozzle 52′, and then is brought into contact with the nip roll 56 through the base material 22 to form the bank 53′, and the active energy ray curable composition A is spread and coated in the width direction of the roll mold 51, is preferable.

(Step C)

Step C is a step of irradiating a region between the outer peripheral surface of the roll mold 51 and the base material 22 with an active energy ray in a state where at least the active energy ray curable composition A is interposed between the outer peripheral surface of the roll mold 51 and the base material 22.

As a method of irradiating with an active energy ray, for example, a method using an active energy ray irradiation device 55′ is exemplified.

Examples of a source for emitting the active energy ray of the active energy ray irradiation device 55′ include a chemical lamp, a low pressure mercury lamp, a high pressure mercury lamp, a metal halide lamp, an electrodeless ultraviolet lamp, a visible light halogen lamp, and a xenon lamp.

The accumulated light quantity of the active energy ray irradiated by the active energy ray irradiation device 55′ is preferably 0.1 J/cm² to 10 J/cm² and more preferably 0.5 J/cm² to 8 J/cm², from the viewpoint of having an excellent curing property of the active energy ray curable composition and suppressing the deterioration of the optical film.

After Step C is finished, cured products of the active energy ray curable composition A and the active energy ray curable composition B are obtained.

(Step D)

Step D is a step of releasing the cured products obtained in Step C from the roll mold 51.

For facilitating the releasing of the cured products from the roll mold 51, surface treatment may be performed on the outer peripheral surface of the roll mold 51 in advance.

Examples of a surface treatment method of the roll mold 51 include plating such as nickel plating, chrome plating, or diamond-like carbon coating; and a method of applying a mold release agent such as a fluorine mold release agent, a silicone mold release agent, or vegetable oil.

(Active Energy Ray Curable Composition A and Active Energy Ray Curable Composition B)

The active energy ray curable composition A constitutes the α-region of the optical film by being cured by irradiation of the active energy ray.

The active energy ray curable composition A may be prepared by appropriately blending components described as the above-described α-region to form a desired α-region.

The active energy ray curable composition B constitutes the β-region of the optical film by being cured by irradiation of the active energy ray.

The active energy ray curable composition B may be prepared by appropriately blending components described as the above-described β-region to form a desired β-region.

The active energy ray curable composition A or the active energy ray curable composition B may contain other components as necessary.

Examples of the other compounds include various additives such as a release agent, a leveling agent, a dispersion stabilizer, and a viscosity modifier.

The viscosity of the active energy ray curable composition A is preferably 10 mPa·s to 3000 mPa·s, more preferably 20 mPa·s to 2500 mPa·s, and even more preferably 30 mPa·s to 2000 mPa·s, from the viewpoint of having excellent handlability at the time of producing the optical film.

The viscosity of the active energy ray curable composition B is preferably 10 mPa·s to 3000 mPa·s, more preferably 20 mPa·s to 2500 mPa·s, and even more preferably 30 mPa·s to 2000 mPa·s, from the viewpoint that it is possible to follow the concave surface of the outer peripheral surface of the roll mold 51 and the handlability at the time of producing the optical film is excellent.

From the viewpoint that it is easy to fill the active energy ray curable composition A and to control the ratios of the α-region and the β-region, the viscosity of the active energy ray curable composition B is preferably lower than the viscosity of the active energy ray curable composition A.

Incidentally, the method for the optical film of the invention by curing the active energy ray curable composition by an active energy ray is described in the above description. However, in the invention, similarly, it is also possible to obtain the optical film of the invention with a thermosetting composition in place of the active energy ray curable composition, by curing the thermosetting composition by heat in place of the active energy ray.

The above-described optical film 20 can be provided at the light emission side of a surface light-emitting body to be described later. Specifically, the optical film 20 can be provided at the light emission side of an organic EL light-emitting element so as to be used as a flat panel display or a lighting device.

(Surface Light-Emitting Body)

A surface light-emitting body of the invention includes the optical film of the invention.

As the surface light-emitting body of the invention, for example, a surface light-emitting body as illustrated in FIG. 5 is exemplified.

Hereinafter, the surface light-emitting body as illustrated in FIG. 5 will be described, but the surface light-emitting body of the invention is not limited to the surface light-emitting body as illustrated in FIG. 5.

The surface light-emitting body illustrated in FIG. 5 includes an organic EL element 40 in which a glass substrate 41, a positive electrode 42, a light emitting layer 43, and a negative electrode 44 are sequentially laminated, and the optical film 20. The optical film 20 is provided on the surface opposite to the surface of the glass substrate 41 on which the organic EL element 40 is formed.

The surface light-emitting body in which the optical film 20 is provided on the organic EL element 40 is excellent in an optical property, particularly, light extraction efficiency. Furthermore, in the surface light-emitting body in which the optical film 20 is provided on the organic EL element 40, optical performance is sufficiently maintained since the optical film 20 is excellent in physical properties, particularly, impact resistance, abrasion resistance, an antifouling property, an antistatic property, and weather resistance.

Incidentally, according to another aspect of the optical film of the invention, there is provided an optical film including a base material and a plurality of convex microlenses arranged on the base material, the microlens having an α-region and a β-region, the β-region occupying the outer portion of the convex shape of the microlens and being positioned so as to cover the α-region, in which a resin composition constituting the α-region has a test result of class 0 or class 1 in an adhesion test in conformity with ISO 2409 for measuring adhesiveness between the base material and the resin composition constituting the α-region, and a difference in light extraction efficiency of a surface light-emitting body before and after a rubbing test of reciprocating a waste cloth 1000 times with a weight of 200 g on the β-region of the optical film is −0.01% to 0.01%.

According to still another aspect of the optical film, there is provided an optical film including a base material and a plurality of convex microlenses arranged on the base material, the microlens having an α-region and a β-region, the β-region occupying the outer portion of the convex shape of the microlens and being positioned so as to cover the α-region, in which an average value of curls at four corners when the 50 mm-square optical film is dried at 60° C. for 4 hours is 1.0 mm or less, and a difference in light extraction efficiency of a surface light-emitting body before and after a rubbing test of reciprocating a waste cloth 1000 times with a weight of 200 g on the β-region of the optical film is −0.01% to 0.01%.

According to still another aspect of the optical film, there is provided an optical film including a base material and a plurality of convex microlenses arranged on the base material, the microlens having an α-region and a β-region, the β-region occupying the outer portion of the convex shape of the microlens and being positioned so as to cover the α-region, in which a resin composition constituting the α-region has a test result of class 0 or class 1 in an adhesion test in conformity with ISO 2409 for measuring adhesiveness between the base material and the resin composition constituting the α-region, an average value of curls at four corners when the 50 mm-square optical film is dried at 60° C. for 4 hours is 1.0 mm or less, and a difference in light extraction efficiency of a surface light-emitting body before and after a rubbing test of reciprocating a waste cloth 1000 times with a weight of 200 g on the β-region of the optical film is −0.01% to 0.01%.

According to still another aspect of the optical film, there is provided an optical film including a base material and a plurality of convex microlenses arranged on the base material, the microlens having an α-region and a β-region, the β-region occupying the outer portion of the convex shape of the microlens and being positioned so as to cover the α-region, in which, in an adhesion test in conformity with ISO 2409 for measuring adhesiveness between the base material and a resin composition constituting the α-region, influence affected on the cross-cut portion is 5% or less, and a surface resistance value of the β-region in a resistivity test in conformity with IEC 60093 is 10¹³ Ω/cm² or less.

According to still another aspect of the optical film, there is provided an optical film including a base material and a plurality of convex microlenses arranged on the base material, the microlens having an α-region and a β-region, the β-region occupying the outer portion of the convex shape of the microlens and being positioned so as to cover the α-region, in which a resin composition constituting the α-region has a test result of class 0 or class 1 in an adhesion test in conformity with ISO 2409 for measuring adhesiveness between the base material and the resin composition constituting the α-region, an average value of curls at four corners when the 50 mm-square optical film is dried at 60° C. for 4 hours is 1.0 mm or less, and a surface resistance value of the β-region in a resistivity test in conformity with IEC 60093 is 10¹³ Ω/cm² or less.

According to still another aspect of the optical film, there is provided an optical film including a base material and a plurality of convex microlenses arranged on the base material, the microlens having an α-region and a β-region, the β-region occupying the outer portion of the convex shape of the microlens and being positioned so as to cover the α-region, in which a resin composition constituting the α-region includes a monomer unit having a bisphenol skeleton, a polyfunctional urethane (meth)acrylate unit, and a polyalkylene glycol di(meth)acrylate unit.

In the optical film, the content ratio of the monomer unit having a bisphenol skeleton to the total mass of the resin composition constituting the α-region is 10 to 80% by mass, the content ratio of the polyfunctional urethane (meth)acrylate unit to the total mass of the resin composition constituting the α-region is 10 to 60% by mass, and the content ratio of the polyalkylene glycol di(meth)acrylate unit to the total mass of the resin composition constituting the α-region is 10 to 50% by mass.

In the optical film, the content ratio of the monomer unit having a bisphenol skeleton to the total mass of the resin composition constituting the α-region is 20 to 65% by mass, the content ratio of the polyfunctional urethane (meth)acrylate unit to the total mass of the resin composition constituting the α-region is 20 to 50% by mass, and the content ratio of the polyalkylene glycol di(meth)acrylate unit to the total mass of the resin composition constituting the α-region is 15 to 40% by mass.

According to still another aspect of the optical film, there is provided an optical film including a plurality of convex microlenses arranged therein, the microlens having an α-region and a β-region, the β-region occupying the outer portion of the convex shape of the microlens and being positioned so as to cover the α-region, and the optical film may be an optical film in which the α-region is formed by a resin composition having at least one performance selected from adhesiveness, impact resistance, and a low curling property, and the β-region is formed by a resin composition having at least one performance selected from abrasion resistance, an antifouling property, flame resistance, an antistatic property, and weather resistance.

The α-region may be formed by a resin composition having the performance of adhesiveness.

The α-region may be formed by a resin composition having the performance of a low curling property.

The β-region may be formed by a resin composition having the performance of abrasion resistance.

According to another aspect of the invention, there is provided an optical film including a plurality of convex microlenses arranged therein, the microlens having an α-region and a β-region, the β-region occupying the outer portion of the convex shape of the microlens and being positioned so as to cover the α-region, and the optical film may be an optical film in which a resin composition constituting the α-region includes a resin having a polyalkylene glycol di(meth)acrylate unit.

According to still another aspect of the invention, there is provided an optical film including a plurality of convex microlenses arranged therein, the microlens having an α-region and a β-region, the β-region occupying the outer portion of the convex shape of the microlens and being positioned so as to cover the α-region, and the optical film may be an optical film in which a resin composition constituting the β-region includes a resin having a trifunctional or higher polyfunctional (meth)acrylate unit.

According to still another aspect of the invention, there is provided an optical film including a plurality of convex microlenses arranged therein, the microlens having an α-region and a β-region, the β-region occupying the outer portion of the convex shape of the microlens and being positioned so as to cover the α-region, and the optical film may be an optical film in which a resin composition constituting the α-region includes a resin having a polyalkylene glycol di(meth)acrylate unit and a resin composition constituting the β-region includes a resin having a trifunctional or higher polyfunctional (meth)acrylate unit.

### EXAMPLES

Hereinafter, the invention will be described in detail by means of Examples, but the invention is not limited to these Examples.

(Adhesion Test (Adhesiveness Evaluation))

The adhesion test is an adhesion test in conformity with ISO 2409, and specifically, the evaluation was conducted by the following method.

11 cuts reaching the base material 22 were formed on the optical film obtained in each of Examples and Comparative Examples using a cutter knife to form 100 grids of lattice pattern (cross cut). At this time, a dedicated cutter guide (trade name “No. 315 Super Cutter Guide,” manufactured by Taiyu Kizai Co., Ltd.) was used. The interval of the cuts was set to 2 mm in this evaluation. An adhesive cellophane tape was pressed firmly onto the lattice pattern portion and the edge of the adhesive cellophane tape was peeled off at once at an angle of 45°. Thereafter, the state of the lattice pattern was compared with the standard drawing described in ISO 2409, and the adhesiveness was evaluated with six grades of class 0 to class 5. A case where a test result is class 0 indicates the highest adhesiveness, and a case where a test result is class 5 indicates the lowest adhesiveness.

(Curling Property Test (Curling Property Evaluation))

The optical film obtained in each of Examples and Comparative Examples was cut into a size of 50 mm square, was dried at 60° C. for 4 hours, was charge-removed by a blower for removal of electrostatic charge (model name “SJ-F020,” manufactured by KEYENCE CORPORATION), and was left to stand still on a flat surface such that the surface having the microlens faces upward. In this state, distances from the flat surface to respective four corners of the optical film were measured by a height gauge (model name “HDS-H30C,” manufactured by Mitutoyo Corporation).

The curling property evaluation was based on an average value (mm) of the distances of respective four corners.

(Rubbing Test (Abrasion Evaluation))

Abrasion marks were formed on the optical film obtained in each of Examples and Comparative Examples by reciprocating a waste cloth 1000 times in total with a weight of 200 g for a distance of 300 mm at a speed of one reciprocation/min, using a rubbing tester (model name “RT-200,” DAIEI KAGAKU SEIKI MFG. CO., LTD).

The abrasion evaluation was based on a value (%) obtained by subtracting the light extraction efficiency of the surface light-emitting body on which the optical film was laminated before the rubbing test from the light extraction efficiency of the surface light-emitting body on which the optical film was laminated after the rubbing test.

(Resistivity Test (Antistatic Property Evaluation))

The surface resistivity was measured by using a resistivity meter (model name “Hiresta UP MCP-HT450 Type,” manufactured by Mitsubishi Chemical Analytech Co., Ltd.) when the surface of the optical film obtained in each of Examples and Comparative Examples was subjected to application of a voltage of 500 V by using a ring probe (URS) and then was maintained for 60 seconds.

(Measurement of Light Extraction Efficiency)

A 0.1 mm-thick light shielding sheet having a hole with a diameter of 10 mm was disposed on the surface light-emitting body, and this was disposed on a sample aperture of an integrating sphere (manufactured by Labsphere, Inc., 6 inch in size). In this state, light emitted from the hole with a diameter of 10 mm of the light shielding sheet when the organic EL element was turned on by allowing a current of 10 mA to flow into the organic EL element was measured by a spectroscopic instrument (spectroscope: model name “PMA-12” (manufactured by Hamamatsu Photonics K.K.), software: software name “U6039-01 ver. 3.3.1 basic software for PMA”) and corrected by a standard luminosity curve, and the number of photons of the surface light-emitting body was calculated.

When the number of photons of the organic EL light-emitting element A was considered as 100%, a ratio (percentage) of the number of photons of the surface light-emitting body was considered as the light extraction efficiency (%).

(Materials Used in Examples and Comparative Examples)

Resin composition A: a resin composition obtained by curing an active energy ray curable composition (1) to be described later by irradiation of an active energy ray (refractive index: 1.52)

Resin composition B: a resin composition obtained by curing an active energy ray curable composition (2) to be described later by irradiation of an active energy ray (refractive index: 1.52)

Resin composition C: a resin composition obtained by curing a mixture obtained by mixing 70% by mass of an active energy ray curable composition (1) to be described later and 30% by mass of fine particles A to be described later with respect to the total mass of a resin composition C, by irradiation of an active energy ray

Resin composition D: a resin composition obtained by curing a mixture obtained by mixing 70% by mass of an active energy ray curable composition (2) to be described later and 30% by mass of fine particles A to be described later with respect to the total mass of a resin composition D, by irradiation of an active energy ray

Resin composition E: a resin composition obtained by curing a mixture obtained by mixing 97% by mass of an active energy ray curable composition (1) to be described later and 3% by mass of an ionic liquid A with respect to the total mass of a resin composition E, by irradiation of an active energy ray

Resin composition F: a resin composition obtained by curing a mixture obtained by mixing 94% by mass of an active energy ray curable composition (1) to be described later and 6% by mass of an ionic liquid A with respect to the total mass of a resin composition F, by irradiation of an active energy ray

Resin composition G: a resin composition obtained by curing an active energy ray curable composition (3) to be described later with respect to the total mass of a resin composition G, by irradiation of an active energy ray

Fine particles A: silicone resin spherical fine particles (trade name “TSR9000,” manufactured by Momentive Performance Materials Inc., refractive index: 1.42, volume average particle diameter: 2 μm)

Ionic liquid A: “Amino Ion AS100” (trade name, manufactured by NIPPON NYUKAZAI CO., LTD., a reaction product of alkanolamine and glycol sulfate ester)

Organic EL element A: an organic EL element in which the optical film on the surface of the light emitting surface side of an organic EL lighting panel kit “Symfos OLED-010K” (manufactured by KONICA MINOLTA, INC.) is removed

(Production of Active Energy Ray Curable Composition (1))

To a glass flask, 117.6 g (0.7 mol) of hexamethylene diisocyanate and 151.2 g (0.3 mol) of isocyanurate-type hexamethylene diisocyanate trimer as a diisocyanate compound, 128.7 g (0.99 mol) of 2-hydroxypropylacrylate and 693 g (1.54 mol) of pentaerythritol triacrylate as hydroxyl group-containing (meth)acrylate, 22.1 g of di-n-butyltin dilaurate as a catalyst, and 0.55 g of hydroquinone monomethyl ether as a polymerization inhibitor were added. After raising the temperature to 75° C., the stirring was continued while the temperature was maintained to 75° C., and the reaction was allowed to occur until the concentration of the isocyanate compound remaining in the flask was 0.1 mol/L or less. As a result of cooling to room temperature, urethane polyfunctional acrylate was obtained.

34.6 parts by mass of the obtained urethane polyfunctional acrylate, 24.7 parts by mass of polybutylene glycol dimethacrylate (trade name “Acryester PBOM,” manufactured by MITSUBISHI RAYON CO., LTD.), 39.5 parts by mass of ethylene oxide-modified bisphenol A dimethacrylate (trade name “New Frontier BPEM-10,” manufactured by DKS Co. Ltd.), and 1.2 parts by mass of 1-hydroxycyclohexyl phenyl ketone (trade name “IRGACURE 184,” manufactured by BASF Japan Ltd.) were mixed with one another to obtain an active energy ray curable composition (1).

(Production of Active Energy Ray Curable Composition (2))

27.8 parts by mass of pentaerythrytol triacrylate (trade name “Viscoat 300,” manufactured by Osaka Organic Chemical Industry Ltd.), 27.8 parts by mass of dipentaerythritol hexaacrylate (trade name “M400,” manufactured by TOAGOSEI CO., LTD.), 27.8 parts by mass of 1,6-hexanediol diacrylate (trade name “Viscoat 230,” manufactured by Osaka Organic Chemical Industry Ltd.), 9.3 parts by mass of urethane acrylate (trade name “UTP-601,” manufactured by Osaka Organic Chemical Industry Ltd.), 1.9 parts by mass of (2,4,6-trimethylphenyl)(diphenylphosphinyl)ketone, and 5.4 parts by mass of 1-hydroxycyclohexyl phenyl ketone (trade name “IRGACURE 184,” manufactured by BASF Japan Ltd.) were mixed with one another to obtain an active energy ray curable composition (2).

(Production of Active Energy Ray Curable Composition (3))

30.0 parts by mass of urethane polyfunctional acrylate obtained by the same method as in the production of the active energy ray curable composition (1), 34.4 parts by mass of polybutylene glycol dimethacrylate (trade name “Acryester PBOM,” manufactured by MITSUBISHI RAYON CO., LTD.), 34.6 parts by mass of ethylene oxide-modified bisphenol A dimethacrylate (trade name “New Frontier BPEM-10,” manufactured by DKS Co. Ltd.), and 1.0 part by mass of 1-hydroxycyclohexyl phenyl ketone (trade name “IRGACURE 184,” manufactured by BASF Japan Ltd.) were mixed with one another to obtain an active energy ray curable composition (3).

(Production of Roll Mold)

On an outer peripheral surface of a steel roll with an outer diameter of 200 mm and an axial direction length of 320 mm, copper plating with a thickness of 200 μm and a Vickers hardness of 230 Hv was performed. The surface of the copper plating layer was coated with a sensitizer, and was subjected to laser light exposure, development, and etching, thereby obtaining a mold having a transferring portion formed therein, in which hemispherical concave shapes having a diameter of 50 μm and a depth of 25 μm are arranged on the copper plating layer in a hexagonal alignment manner at the minimum interval of 3 μm. On the surface of the obtained mold, chrome plating was performed to give an anti-corrosion property and durability, and thus a roll mold was obtained.

Incidentally, a width of a region in which the concave transferring portion is present on the roll mold is 280 mm, the region is provided at a center of 320 mm, which is the length of the roll mold in the axial direction, and both ends of the roll mold in the axial direction were made mirror plane regions.

(Production of Surface Light-Emitting Body)

On the light emitting surface side of the organic EL element, Cargille standard refractive index liquid (refractive index of 1.52, manufactured by MORITEX Corporation) was coated as the adhesive layer 23. The surface of the base material of the optical film having the base material thus obtained was subjected to optical adhesion to thereby obtain a surface light-emitting body.

### Example 1

### Production of Optical Film

Using the active energy ray curable composition (1) as the active energy ray curable composition A for constituting the α-region, and the active energy ray curable composition (2) as the active energy ray curable composition B for constituting the β-region, an optical film was produced by performing Step A (the coating includes making the active energy ray curable composition B follow the surface of the concave microlens transferring portion), Step X, Step B, Step C, and Step D in this order, using the apparatus illustrated in FIG. 6. In the microlens of the optical film thus obtained, the α-region was formed by the resin composition A, the β-region was formed by the resin composition B, the average maximum diameter Lₐᵥₑ of the bottom surface portion of the microlens was 50 μm, the average height Hₐᵥₑ of the microlens was 25 μm, the average height hₐᵥₑ of the α-region was 18 μm, and the microlens had a spherical segment shape approximately corresponding to the size of the concave shape of the roll mold. In addition, the base layer of the optical film thus obtained was formed by the same component as that of the α-region and had a thickness of 20 μm.

The results of the adhesion test, the rubbing test, and the curling property test of the optical film thus obtained are shown in Table 1.

TABLE 1

| | | | Evaluation result | | |
|---|---|---|---|---|---|
| | | | Adhesion | Warpage | Rubbing |
| | Optical film | | test | test | test |
| | α-region | β-region | (class) | (mm) | (%) |
| Example 1 | Resin | Resin | 0 | 0.18 | 0.003 |
| | compos- | composi- | | | |
| | ition A | tion B | | | |
| Comparative | Resin | Resin | 0 | 0.67 | −0.016 |
| Example 1 | composi- | composi- | | | |
| | tion A | tion A | | | |
| Comparative | Resin | Resin | 0 | 2.25 | −0.013 |
| Example 2 | composi- | composi- | | | |
| | tion B | tion B | | | |

Incidentally, a polyester film (trade name “DIAFOIL T910E125,” manufactured by Mitsubishi Plastics, Inc., 340 mm in width, 125 μm in thickness) was used as the base material 22, the above-described roll mold was used as the roll mold 51, a plastic doctor blade (trade name “Maniveil,” manufactured by ECO BLADE, Inc., 0.35 mm in thickness, with tapered blade edge) was used as the doctor blade 54, an ultraviolet irradiation device (model name “SP-7,” manufactured by USHIO INC.) was used as the active energy ray irradiation device 55, an ultraviolet irradiation device (model name “Light Hammer 6,” manufactured by Fusion UV Systems Inc.) was used as the active energy ray irradiation device 55′, and a rubber roller (trade name “Granpaul UV,” manufactured by MIYAKAWA ROLLER Co., Ltd., 60 degrees in rubber hardness of surface) was used as the nip roll 56 and the hold-down roll 56′.

Furthermore, the production conditions were as follows.

The travel speed of the base material 22 was set to 3 m/min, the rotation speed of the roll mold 51 was set to 3 m/min, the surface temperature of the roll mold 51 was set to 40° C., the temperatures of the active energy ray curable composition A and the active energy ray curable composition B were set to 25° C., and the viscosities of the active energy ray curable composition A and the active energy ray curable composition B were set to 700 mPa·s.

As a method of applying the active energy ray curable composition B, a method in which the active energy ray curable composition B is added dropwise to the roll mold 51 using the nozzle 52, and then is brought into contact with the doctor blade 54 to form the bank 53, and the active energy ray curable composition B is spread and coated in the width direction of the roll mold 51 was used. In this application method, the active energy ray curable composition B was made to follow the surface of the concave microlens transferring portion on the outer peripheral surface of the roll mold 51.

As a method of supplying the active energy ray curable composition A, a method in which the active energy ray curable composition A is added dropwise to the roll mold 51 coated with the active energy ray curable composition B using the nozzle 52′, and then is brought into contact with the nip roll 56 through the base material 22 to form the bank 53′, and the active energy ray curable composition A is spread and coated in the width direction of the roll mold 51 was used.

An ultraviolet ray of 0.2 J/cm² in the accumulated light quantity was emitted from the active energy ray irradiation device 55 and an ultraviolet ray of 0.76 J/cm² in the accumulated light quantity was emitted from the active energy ray irradiation device 55′.

### Comparative Examples 1 and 2

An optical film was obtained by performing the same operation as in Example 1, except that the α-region and the β-region of the optical film were changed to be formed by resin compositions shown in Table 1.

The results of the adhesion test, the curling property test, and the rubbing test of the optical film thus obtained are shown in Table 1.

### Example 2 and Comparative Examples 3 and 4

An optical film was obtained by performing the same operation as in Example 1, except that the α-region and the β-region of the optical film were changed to be formed by resin compositions shown in Table 2.

The results of the adhesion test, the curling property test, and the rubbing test of the optical film thus obtained are shown in Table 2.

TABLE 2

| | | | Evaluation result | | |
|---|---|---|---|---|---|
| | | | Adhesion | Warpage | Rubbing |
| | Optical film | | test | test | test |
| | α-region | β-region | (class) | (mm) | (%) |
| Example 2 | Resin | Resin | 0 | 0.76 | 0.003 |
| | composi- | composi- | | | |
| | tion C | tion D | | | |
| Comparative | Resin | Resin | 0 | 0.98 | −0.025 |
| Example 3 | composi- | composi- | | | |
| | tion C | tion C | | | |
| Comparative | Resin | Resin | 0 | 2.60 | −0.011 |
| Example 4 | composi- | composi- | | | |
| | tion D | tion D | | | |

### Example 3 and Comparative Examples 1 and 5

An optical film was obtained by performing the same operation as in Example 1, except that the α-region and the β-region of the optical film were changed to be formed by resin compositions shown in Table 3.

The results of the adhesion test, the curling property test, and the resistivity test of the optical film thus obtained are shown in Table 3.

TABLE 3

| | | | Evaluation result | | |
|---|---|---|---|---|---|
| | | | Adhesion | Warpage | Resistivity |
| | Optical film | | test | test | test |
| | α-region | β-region | (class) | (mm) | (W/cm²) |
| Example 3 | Resin | Resin | 0 | 0.15 | 1 × 10¹⁰ |
| | composi- | composi- | | | |
| | tion A | tion E | | | |
| Comparative | Resin | Resin | 0 | 0.12 | 10¹⁴ or |
| Example 1 | composi- | composi- | | | more |
| | tion A | tion A | | | |
| Comparative | Resin | Resin | 3 | 0.14 | 8 × 10⁸ |
| Example 5 | composi- | composi- | | | |
| | tion E | tion E | | | |

### Example 4 and Comparative Example 6

An optical film was obtained by performing the same operation as in Example 1, except that the α-region and the β-region of the optical film were changed to be formed by resin compositions shown in Table 4.

The results of the adhesion test, the curling property test, and the resistivity test of the optical film thus obtained are shown in Table 4.

TABLE 4

| | | | Evaluation result | | |
|---|---|---|---|---|---|
| | | | Adhesion | Warpage | Resistivity |
| | Optical film | | test | test | test |
| | α-region | β-region | (class) | (mm) | (W/cm²) |
| Example 4 | Resin | Resin | 0 | 0.23 | 3 × 10⁹ |
| | composi- | composi- | | | |
| | tion A | tion F | | | |
| Comparative | Resin | Resin | 0 | 0.12 | 10¹⁴ or |
| Example 1 | composi- | composi- | | | more |
| | tion A | tion A | | | |
| Comparative | Resin | Resin | 4 | 0.21 | 4 × 10⁸ |
| Example 6 | composi- | composi- | | | |
| | tion F | tion F | | | |

### Example 5 and Comparative Example 7

An optical film was obtained by performing the same operation as in Example 1, except that the α-region and the β-region of the optical film were changed to be formed by resin compositions shown in Table 5.

The results of the adhesion test, the curling property test, and the resistivity test of the optical film thus obtained are shown in Table 5.

TABLE 5

| | | | Evaluation result | | |
|---|---|---|---|---|---|
| | | | Adhesion | Warpage | Resistivity |
| | Optical film | | test | test | test |
| | α-region | β-region | (class) | (mm) | (W/cm²) |
| Example 5 | Resin | Resin | 0 | 0.27 | 1 × 10¹⁰ |
| | composi- | composi- | | | |
| | tion G | tion F | | | |
| Comparative | Resin | Resin | 0 | 0.18 | 10¹⁴ or |
| Example 7 | composi- | composi- | | | more |
| | tion G | tion G | | | |
| Comparative | Resin | Resin | 4 | 0.21 | 4 × 10⁸ |
| Example 6 | composi- | composi- | | | |
| | tion F | tion F | | | |

### Example 6

An optical film was obtained by performing the same operation as in Example 1, except that the α-region and the β-region of the optical film were changed to be formed by resin compositions shown in Table 6.

The results of the adhesion test, the curling property test, and the rubbing test of the optical film thus obtained are shown in Table 6.

TABLE 6

| | | | Evaluation result | | |
|---|---|---|---|---|---|
| | | | Adhesion | Warpage | Rubbing |
| | Optical film | | test | test | test |
| | α-region | β-region | (class) | (mm) | (%) |
| Example 6 | Resin | Resin | 0 | 0.46 | 0.004 |
| | composi- | composi- | | | |
| | tion G | tion B | | | |
| Comparative | Resin | Resin | 0 | 0.18 | −0.025 |
| Example 7 | composi- | composi- | | | |
| | tion G | tion G | | | |
| Comparative | Resin | Resin | 0 | 2.25 | −0.013 |
| Example 2 | composi- | composi- | | | |
| | tion B | tion B | | | |

As seen from Table 1 and Table 2, the optical film of each of Example 1 and Example 2 included in the scope of the invention was excellent in all of a low curling property, adhesiveness, and abrasion resistance since the α-region has a low curing property and adhesiveness and the β-region has abrasion resistance. On the other hand, the optical film of each of Comparative Examples 1 to 4 in which the α-region and the β-region have only any performance of a low curling property, adhesiveness, and abrasion resistance was not excellent in all of a low curling property, adhesiveness, and abrasion resistance.

As seen from Table 3 to Table 5, the optical film of each of Example 3 to Example 5 included in the scope of the invention was excellent in all of a low curling property, abrasion resistance, and an antistatic property since the α-region has a low curling property and the β-region has abrasion resistance and an antistatic property. On the other hand, the optical film of each of Comparative Examples 1, 5, 6, and 7 in which the α-region and the β-region have only any performance of a low curling property, abrasion resistance, and an antistatic property was not excellent in all of a low curling property, abrasion resistance, and an antistatic property.

As seen from Table 6, the optical film of Example 6 included in the scope of the invention was excellent in all of a low curling property, adhesiveness, and abrasion resistance since the α-region has a low curing property and adhesiveness and the β-region has abrasion resistance and an antistatic property. On the other hand, the optical film of each of Comparative Examples 2 and 7 in which the α-region and the β-region have only any performance of a low curling property, adhesiveness, and abrasion resistance was not excellent in all of a low curling property, adhesiveness, and abrasion resistance.

### INDUSTRIAL APPLICABILITY

According to the optical film of the invention, it is possible to obtain a surface light-emitting body which is excellent in an optical property, particularly, light extraction efficiency, and this surface light-emitting body can be used suitably for, for example, lighting devices, displays, or screens.

### EXPLANATIONS OF LETTERS OR NUMERALS

10 MICROLENS
11 α-REGION
12 β-REGION
13 BOTTOM SURFACE PORTION
20 OPTICAL FILM
21 BASE LAYER
22 BASE MATERIAL
23 ADHESIVE LAYER
24 PROTECTIVE FILM
25 INTERMEDIATE LAYER
40 ORGANIC EL ELEMENT
41 GLASS SUBSTRATE
42 POSITIVE ELECTRODE
43 LIGHT EMITTING LAYER
44 NEGATIVE ELECTRODE
50 PRODUCING APPARATUS FOR OPTICAL FILM
51 ROLL MOLD
52 NOZZLE
52′ NOZZLE
53 BANK
53′ BANK
54 DOCTOR BLADE
55 ACTIVE ENERGY RAY IRRADIATION DEVICE
55′ ACTIVE ENERGY RAY IRRADIATION DEVICE
56 NIP ROLL
56′ NIP ROLL

1. An optical film comprising a base material and a plurality of convex microlenses arranged on the base material, the microlens having an α-region and a β-region, the β-region occupying the outer portion of the convex shape of the microlens and being positioned so as to cover the α-region, wherein
a resin composition constituting the α-region has a test result of class 0 or class 1 in an adhesion test in conformity with ISO 2409 for measuring adhesiveness between the base material and the resin composition constituting the α-region.

2. The optical film according to claim 1, wherein the resin composition constituting the α-region includes at least one unit selected from the group consisting of a monomer unit having a bisphenol skeleton and a polyfunctional urethane (meth)acrylate unit.

3. The optical film according to claim 1, further comprising a primer layer including a urethane resin between the base material and the microlens.

4. An optical film comprising a plurality of convex microlenses arranged therein, the microlens having an α-region and a β-region, the β-region occupying the outer portion of the convex shape of the microlens and being positioned so as to cover the α-region, wherein
an average value of curls at four corners when the 50 mm-square optical film is dried at 60° C. for 4 hours is 1.0 mm or less.

5. The optical film according to claim 4, wherein a resin composition constituting the α-region includes at least one unit selected from the group consisting of a polyoxyalkylene glycol di(meth)acrylate unit, a polyester polyol di(meth)acrylate unit, and an aromatic ester diol di(meth)acrylate unit.

6. The optical film according to claim 5, wherein the total content ratio of the polyoxyalkylene glycol di(meth)acrylate unit, the polyester polyol di(meth)acrylate unit, and the aromatic ester diol di(meth)acrylate unit to the total mass of the resin composition constituting the α-region is 10% by mass or more.

7. An optical film comprising a plurality of convex microlenses arranged therein, the microlens having an α-region and a β-region, the β-region occupying the outer portion of the convex shape of the microlens and being positioned so as to cover the α-region, wherein
a difference in light extraction efficiency of a surface light-emitting body before and after a rubbing test of reciprocating a waste cloth 1000 times with a weight of 200 g on the β-region of the optical film is −0.01% to 0.01%.

8. The optical film according to claim 7, wherein a resin composition constituting the β-region includes a trifunctional or higher polyfunctional (meth)acrylate unit.

9. The optical film according to claim 8, wherein the trifunctional or higher polyfunctional (meth)acrylate unit is at least one trifunctional or higher polyfunctional (meth)acrylate unit selected from the group consisting of pentaerythritol tri(meth)acrylate, dipentaerythritol penta(meth)acrylate, dipentaerythritol hexa(meth)acrylate, and tris(2-(meth)acryloyloxyethyl)isocyanurate.

10. The optical film according to claim 8, wherein a content ratio of the trifunctional or higher polyfunctional (meth)acrylate unit to the total mass of the resin composition constituting the β-region is 30% by mass or more.

11. An optical film comprising a plurality of convex microlenses arranged therein, the microlens having an α-region and a β-region, the β-region occupying the outer portion of the convex shape of the microlens and being positioned so as to cover the α-region, wherein
a surface resistance value of the β-region in a resistivity test in conformity with IEC 60093 is 10¹³ Ω/cm² or less.

12. The optical film according to claim 11, wherein a resin composition constituting the β-region includes at least one material selected from the group consisting of an ionic liquid, a quaternary ammonium compound, an ionic surfactant, and a conductive polymer.

13. The optical film according to claim 12, wherein the resin composition constituting the β-region includes an ionic liquid.

14. A method for producing the optical film according to claim 1, the method comprising:
while a roll mold having an outer peripheral surface on which a plurality of concave microlens transferring portions are arranged is rotated and a base material is allowed to travel in a rotational direction of the roll mold along the outer peripheral surface of the roll mold, coating the outer peripheral surface of the roll mold with an active energy ray curable composition B to fill a part of the concave shapes of the microlens transferring portions with the active energy ray curable composition B;
supplying an active energy ray curable composition A to a space between the outer peripheral surface of the roll mold and the base material;
irradiating a region between the outer peripheral surface of the roll mold and the base material with an active energy ray in a state where at least the active energy ray curable composition A is interposed between the outer peripheral surface of the roll mold and the base material to obtain cured products of the active energy ray curable composition A and the active energy ray curable composition B; and
releasing the cured products from the roll mold.

15. The method for producing the optical film according to claim 14, wherein the application of the active energy ray curable composition B in the filling with the active energy ray curable composition B is coating for making the active energy ray curable composition B follow a surface of the concave microlens transferring portion on the outer peripheral surface of the roll mold.

16. The method for producing the optical film according to claim 14, further comprising irradiating the active energy ray curable composition B with an active energy ray to cure the active energy ray curable composition B between the filling with the active energy ray curable composition B and the supplying of the active energy ray curable composition A.

17. The method for producing the optical film according to claim 14, wherein a viscosity of the active energy ray curable composition B is lower than a viscosity of the active energy ray curable composition A.

18. A surface light-emitting body comprising the optical film according to claim 1.
